(19) United States
(12) Patent Application Publication
(10) Pub. No.: US 2025/0241205 A1
(43) Pub. Date: Jul. 24, 2025

(54) INFRARED SENSOR

(71) Applicant: Panasonic Intellectual Property Management Co., Ltd., Osaka (JP)

(72) Inventor: KUNIHIKO NAKAMURA, Osaka (JP)

(21) Appl. No.: 19/174,779

(22) Filed: Apr. 9, 2025

Related U.S. Application Data
(63) Continuation of application No. PCT/JP2023/036730, filed on Oct. 10, 2023.

(30) Foreign Application Priority Data
Oct. 25, 2022 (JP) 2022-170918

(51) Int. Cl. H10N 10/17; G01J 5/00; G01J 5/12; G01J 5/14

(52) U.S. Cl. CPC H10N 10/17; G01J 5/14; G01J 2005/0077; G01J 2005/123

(57) ABSTRACT

An infrared sensor includes a light receiver; and a thermoelectric converter that generates an infrared detection signal based on heat generated by the light receiver. The thermoelectric converter includes an n-type MOSFET, a p-type MOSFET, a hot junction metal electrode, a first cold junction metal electrode, and a second cold junction metal electrode. The hot junction metal electrode is located on the light receiver or adjacent to the light receiver, and is in ohmic contact with a drain of the n-type MOSFET and a drain of the p-type MOSFET. The first cold junction metal electrode is in ohmic contact with a source of the n-type MOSFET. The second cold junction metal electrode is in ohmic contact with a source of the p-type MOSFET.

### BACKGROUND

### 1. Technical Field

The present disclosure relates to an infrared sensor.

### 2. Description of the Related Art

An infrared sensor using an infrared sensor element that detects infrared rays using heat generated as a result that a light receiver receives the infrared rays is known. As such an infrared sensor, an infrared imaging device (infrared image sensor) in which infrared sensor elements are arranged in an array as pixels is known. In order to acquire a high-definition infrared image by a small imaging device with many pixels arranged at a high density, there is a method of decreasing the area of the infrared sensor elements per pixel. This can be implemented by a semiconductor manufacturing process at increasingly fine geometries. The signal generated from the infrared sensor elements per pixel is processed by an analog front end. The analog front end is hereinafter referred to as “AFE”. The AFE mainly includes, for example, an amplifier, a filter, and an analog-to-digital (AD) converter. When an infrared sensor includes one AFE for infrared sensor elements, a pixel selection switch that selects at least one of the infrared sensor elements and connects the selected infrared sensor element to the AFE is provided between the infrared sensor and the AFE. The pixel to be selected is switched by the pixel selection switch at a certain time interval, and hence scanning of the pixel can be implemented. In other words, infrared detection signals are output from the sequentially selected pixels. The pixel selection switch and the AFE can be also implemented by the semiconductor manufacturing process at fine geometries. The infrared sensor elements, the pixel selection switch, and the AFE can be integrated on the same semiconductor substrate, or at least one of them can be produced as a separate chip and integrated by mounting.

However, when the area of a light receiver of an infrared sensor element is decreased, the power of infrared rays to be received becomes weak. Further, when the light receiver having the small area is used, it is difficult to obtain a spatial temperature difference. In an infrared sensor element using a thermocouple, a thermopile, or the like, which uses the Seebeck effect, that is, an electromotive force based on a temperature difference as an infrared detection signal, the electromotive force becomes weak when the temperature difference becomes small, and the signal-to-noise (signal/noise, S/N) ratio decreases. Regarding this problem, International Publication No. 2019/225058 discloses a technique of supporting a light receiver in midair by a hollow support having a phononic crystal structure with excellent thermal insulation in an infrared sensor. Accordingly, it is possible to suppress a decrease in S/N ratio while maintaining the spatial temperature difference. Specifically, in a thermopile infrared sensor structure including a substrate, a light receiver separated from the substrate, and a hollow support that supports the light receiver while separating the light receiver above the substrate, a phononic crystal structure is provided in the hollow support, a cold junction is provided on the substrate side, and a hot junction is provided on the light receiver side. As a result, the temperature difference between the hot junction temperature on the light receiver, which has been changed by the radiation of infrared rays, and the cold junction temperature can be easily maintained due to the high thermal insulation of the phononic crystal structure, and the electromotive force due to the Seebeck effect can be effectively obtained.

### SUMMARY

One non-limiting and exemplary embodiment provides an infrared sensor capable of increasing the detection accuracy of infrared rays.

In one general aspect, the techniques disclosed here feature an infrared sensor including a light receiver; and a thermoelectric converter that generates an infrared detection signal based on heat generated by the light receiver. The thermoelectric converter includes an n-type metal oxide semiconductor field effect transistor, which is referred to as MOSFET, a p-type MOSFET, a hot junction metal electrode, a first cold junction metal electrode, and a second cold junction metal electrode. The hot junction metal electrode is located on the light receiver or adjacent to the light receiver, and is in ohmic contact with a drain of the n-type MOSFET and a drain of the p-type MOSFET. The first cold junction metal electrode is in ohmic contact with a source of the n-type MOSFET. The second cold junction metal electrode is in ohmic contact with a source of the p-type MOSFET.

According to the present disclosure, the detection accuracy of infrared rays can be increased.

Additional benefits and advantages of the disclosed embodiments will become apparent from this specification and drawings. The benefits and/or advantages may be individually obtained by the various embodiments and features of this specification and drawings, which need not all be provided in order to obtain one or more of such benefits and/or advantages.

### BRIEF DESCRIPTION OF THE DRAWINGS

FIG. 1 is a block diagram illustrating an overall configuration of an infrared sensor according to Embodiment 1;

FIG. 2 is a sectional view illustrating an infrared sensor element according to Embodiment 1;

FIG. 3 is a plan view of the infrared sensor element according to Embodiment 1 as viewed from above;

FIG. 4A is a diagram for explaining an operation in a noise measurement mode of the infrared sensor according to Embodiment 1;

FIG. 4B is a diagram for explaining an operation in an infrared measurement mode of the infrared sensor according to Embodiment 1;

FIG. 5 is a block diagram illustrating an overall configuration of an infrared sensor according to Embodiment 2;

FIG. 6A is a diagram for explaining an operation in the noise measurement mode of the infrared sensor according to Embodiment 2;

FIG. 6B is a diagram for explaining an operation in the infrared measurement mode of the infrared sensor according to Embodiment 2;

FIG. 7 is a diagram illustrating a configuration of an infrared sensor according to Embodiment 3;

FIG. 8 is a diagram illustrating an example of a waveform of a voltage output from a voltage supply circuit according to Embodiment 3;

FIG. 9 is a sectional view illustrating an infrared sensor element according to Embodiment 4;

FIG. 10 is a plan view of the infrared sensor element according to Embodiment 4 as viewed from above;

FIG. 11 is a sectional view illustrating an infrared sensor element according to a modification of Embodiment 4;

FIG. 12 is a sectional view illustrating an infrared sensor element according to Embodiment 5;

FIG. 13 is a sectional view illustrating an infrared sensor element according to a modification of Embodiment 5;

FIG. 14 is a sectional view illustrating an infrared sensor element according to Embodiment 6;

FIG. 15A is a plan view of a portion of a channel region of an n-type MOSFET according to Embodiment 6 as viewed from above;

FIG. 15B is a plan view of a portion of a channel region of a p-type MOSFET according to Embodiment 6 as viewed from above;

FIG. 16A is a sectional view of the portion of the channel region of the n-type MOSFET according to Embodiment 6; and

FIG. 16B is a sectional view of the portion of the channel region of the p-type MOSFET according to Embodiment 6.

### DETAILED DESCRIPTIONS

### Underlying Knowledge Forming Basis of the Present Disclosure

In infrared sensors, an improvement in detection accuracy of infrared rays is required. The technique described in International Publication No. 2019/225058 is a technique for improving (increasing) the S component of the S/N ratio to improve the detection accuracy of infrared rays. On the other hand, it is also possible to improve (reduce) the N component of the S/N ratio to improve the detection accuracy of infrared rays. For example, as a method of improving the N component of the S/N ratio, there is a method of canceling a drift (in other words, an offset component) of an offset voltage generated in an amplifier and 1/f noise by signal processing. As one example of a specific method, there is exemplified a method of providing a mechanical shutter between an infrared sensor and an infrared source and processing signals obtained by opening and closing the mechanical shutter.

In this method, as a first stage, output information by an AFE when the shutter is “closed” is acquired. In other words, the output information output from the AFE in a state in which no infrared detection signal is output from an infrared sensor element to the AFE is acquired. Such a processing method in which the information is output from the AFE in the state in which no infrared detection signal is output from the infrared sensor element to the AFE may be referred to as a “noise measurement mode” below. The output information of the AFE when the shutter is “closed” is the offset component of the amplifier and the 1/f noise, and does not include information derived from the infrared rays.

Next, as a second stage, output information by the AFE when the shutter is “open” is acquired. In other words, the infrared detection signal is output from the infrared sensor element to the AFE, the infrared detection signal is processed in the AFE, and output information after the processing is acquired. Such a processing method in which the infrared detection signal is output from the infrared sensor element to the AFE and the infrared detection signal is processed by the AFE to output the information may be hereinafter referred to as an “infrared measurement mode”. The output information of the AFE when the shutter is “open” is information with the offset component of the amplifier and the 1/f noise added to the information derived from the infrared rays.

Finally, as a third stage, the output information of the first stage is subtracted from the output information of the second stage. The subtracted output information is infrared information in which the offset component of the amplifier and the 1/f noise have been canceled (removed) from the information based on the infrared detection signal. As a result, the N component of the S/N ratio is reduced, and the detection accuracy of the infrared sensor can be improved. The output information of the AFE acquired in the first stage and the second stage may be converted into digital information encoded by an AD converter. Accordingly, the difference calculation processing in the third stage can be facilitated. The order of the noise measurement mode and the infrared measurement mode may be reversed. Whichever of the noise measurement mode and the infrared measurement mode is performed first, the two measurement modes of the noise measurement mode and the infrared measurement mode are performed in a short time in which the drift of the offset voltage of the amplifier and the change of the 1/f noise are negligible.

Since the mechanical shutter is not suitable for a small imaging device, the opening and closing of the shutter is artificially substituted by a semiconductor switch, and the noise measurement mode and the infrared measurement mode can be implemented by using the semiconductor switch. For example, the noise measurement mode and the infrared measurement mode can be switched by an operation of the semiconductor switch. Hereinafter, such a semiconductor switch may be referred to as a “measurement mode changeover switch”. The above-described pixel selection switch also functions as, for example, the measurement mode changeover switch. For example, even when the infrared sensor element generates the infrared detection signal, the noise measurement mode is implemented by turning off (closing) the measurement mode changeover switch provided between the infrared sensor element and the AFE to make the infrared sensor element and the AFE non-conductive, and the infrared measurement mode is implemented by turning on (opening) the measurement mode changeover switch to make the infrared sensor element and the AFE conductive.

The inventor of the present disclosure has found that the following problem occurs when the measurement mode is switched using such a semiconductor switch.

A semiconductor switch using a normal semiconductor device is generally superior to a mechanical switch in high-speed switching, but has a problem in isolation (insulation). In other words, the poor isolation means that even when the switch is in the off state, a current slightly leaks and the resistance of the switch cannot be regarded as infinite in some cases. Thus, the stronger the signal intensity of the infrared detection signal generated by the infrared sensor element, the larger the signal leaking from the measurement mode changeover switch in the off state. That is, when the signal intensity of the infrared detection signal generated by the infrared sensor element is strong, in the noise measurement mode, the infrared detection signal that cannot be completely interrupted by the measurement mode changeover switch is output to the AFE, and the offset component of the amplifier and the 1/f noise cannot be accurately figured out.

Moreover, in the case of a configuration in which one AFE is connected to pixels, in the infrared measurement mode, when the infrared detection signal that cannot be completely interrupted leaks from the pixel selection switch of the non-selected pixel and is input to the AFE while being superimposed on the infrared detection signal of the selected pixel, the infrared information on the selected pixel cannot be accurately figured out.

The inventor of the present disclosure has focused on the problem that, in implementing an infrared sensor with high detection accuracy, the infrared detection signal leaks due to the characteristics of the semiconductor switch, and the detection accuracy of the infrared sensor is decreased. As a result of intensive studies, the inventor of the present disclosure has found that the above-described problem can be addressed by a configuration in which the function of the infrared sensor element to generate the infrared detection signal can be temporarily lost, and has thus obtained the one general aspect of the present disclosure. Details are described below.

### Overview of Present Disclosure

Examples of an infrared sensor according to the present disclosure will be described below.

An infrared sensor according to a first aspect of the present disclosure includes a light receiver; and a thermoelectric converter that generates an infrared detection signal based on heat generated by the light receiver. The thermoelectric converter includes an n-type metal oxide semiconductor field effect transistor, which is referred to as MOSFET, a p-type MOSFET, a hot junction metal electrode, a first cold junction metal electrode, and a second cold junction metal electrode. The hot junction metal electrode is located on the light receiver or adjacent to the light receiver, and is in ohmic contact with a drain of the n-type MOSFET and a drain of the p-type MOSFET. The first cold junction metal electrode is in ohmic contact with a source of the n-type MOSFET. The second cold junction metal electrode is in ohmic contact with a source of the p-type MOSFET.

According to this configuration, it is possible to suppress mixing of an unintended infrared detection signal and to increase the detection accuracy of infrared rays.

Specifically, when the infrared detection signal is not desired to be output from the thermoelectric converter as in the noise measurement mode, a gate voltage at which an n-type channel is not formed is applied to the n-type MOSFET, and a gate voltage at which a p-type channel is not formed is applied to the p-type MOSFET. Accordingly, a configuration having a thermoelectric conversion function electrically connected in series to “cold junction-n-type semiconductor-hot junction-p-type semiconductor-cold junction” is not formed in the thermoelectric converter. In other words, even when the light receiver receives infrared rays and a temperature difference is generated between the hot junction and the cold junction, in the thermoelectric converter, thermoelectric conversion due to the Seebeck effect is not performed. Thus, for example, in the noise measurement mode, the offset component of the amplifier and the 1/f noise can be measured without the infrared detection signal from the thermoelectric converter being mixed.

Moreover, according to this configuration, for example, when one thermoelectric converter is selected from thermoelectric converters and used for the purpose with which the infrared detection signal is output, a gate voltage at which the n-type channel is formed is applied to the n-type MOSFET, and a gate voltage at which the p-type channel is formed is applied to the p-type MOSFET in the selected thermoelectric converter. Accordingly, the configuration having the thermoelectric conversion function electrically connected in series to “cold junction-n-type semiconductor-hot junction-p-type semiconductor-cold junction” is formed in the thermoelectric converter. Thus, in the thermoelectric converter, the thermoelectric conversion due to the Seebeck effect is performed, and the infrared detection signal is generated. On the other hand, in the non-selected thermoelectric converter, the gate voltage at which the n-type channel is not formed is applied to the n-type MOSFET, and the gate voltage at which the p-type channel is not formed is applied to the p-type MOSFET. Accordingly, the configuration having the thermoelectric conversion function as described above is not formed, and the thermoelectric conversion is not performed. Thus, in the non-selected thermoelectric converter, the infrared detection signal is not generated, and it is possible to suppress the disturbance to the infrared detection signal generated from the selected thermoelectric converter.

For example, an infrared sensor according to a second aspect of the present disclosure, which is the infrared sensor according to the first aspect, further includes an amplifier that amplifies the infrared detection signal generated by the thermoelectric converter. The amplifier is a voltage-input amplifier.

According to this configuration, when the thermoelectric converter outputs the infrared detection signal to the amplifier, a current hardly flows from the thermoelectric converter to the amplifier due to the high input impedance of the voltage-input amplifier. Thus, when the thermoelectric converter outputs the infrared detection signal to the amplifier, a current contributing to the exhibition of the Peltier effect opposite to the Seebeck effect is unlikely to be generated in the thermoelectric converter. Hence the temperature distribution of the thermoelectric converter is hardly changed, and an error is unlikely to occur even when the output of the amplifier is read immediately after the output of the infrared detection signal. For example, when the measurement mode is switched from the noise measurement mode to the infrared measurement mode, the magnitude of the current flowing through the thermoelectric converter hardly changes before and after the switching time, and hence the temperature distribution of the thermoelectric converter hardly changes. Hence, even when the output from the amplifier is read immediately after the switching, an error occurring in the process of redistributing the temperature distribution is suppressed, and a high S/N ratio can be ensured. Thus, the infrared sensor according to the present aspect can perform a high-speed detection operation with high accuracy.

For example, an infrared sensor according to a third aspect of the present disclosure, which is the infrared sensor according to the first aspect or the second aspect, further includes a substrate. The light receiver, the n-type MOSFET, and the p-type MOSFET are located above the substrate. A gap is formed between the light receiver, the n-type MOSFET, and the p-type MOSFET, and the substrate.

According to this configuration, since the periphery of the light receiver is a gas such as air or a gas such as decompressed air having low thermal conductivity, most of the heat generated in the light receiver by the infrared radiation only flows to the cold junction side via the p-type MOSFET and the n-type MOSFET, and it is easy to ensure the temperature difference between the hot junction and the cold junction. Thus, an infrared detection signal with a high S/N ratio can be acquired.

For example, in an infrared sensor according to a fourth aspect of the present disclosure, which is the infrared sensor according to the third aspect, at least one of a gate of the n-type MOSFET or a gate of the p-type MOSFET has a phononic crystal structure.

According to this configuration, the thermal insulation of the gate of the at least one of the p-type MOSFET or the n-type MOSFET is increased, and hence it is easy to ensure the temperature difference between the hot junction and the cold junction. Thus, an infrared detection signal with a high S/N ratio can be acquired.

For example, in an infrared sensor according to a fifth aspect of the present disclosure, which is the infrared sensor according to the third aspect or the fourth aspect, at least one of the source, the drain, or a channel region of each of the n-type MOSFET and the p-type MOSFET has a phononic crystal structure.

According to this configuration, the thermal insulation of the portions having the phononic crystal structure in the p-type MOSFET and the n-type MOSFET is increased. Hence it is easy to ensure the temperature difference between the hot junction and the cold junction. Thus, an infrared detection signal with a high S/N ratio can be acquired.

For example, in an infrared sensor according to a sixth aspect of the present disclosure, which is the infrared sensor according to any one of the third aspect to the fifth aspect, a channel region of at least one of the n-type MOSFET or the p-type MOSFET has a phononic crystal structure. A gate of the at least one of the n-type MOSFET or the p-type MOSFET is formed on an inner wall of a pore of the phononic crystal structure.

According to this configuration, the volume of the gate of the at least one of the p-type MOSFET or the n-type MOSFET can be minimized, and the thermal insulation of the at least one of the p-type MOSFET or the n-type MOSFET is increased. Hence it is easy to ensure the temperature difference between the hot junction and the cold junction. Thus, an infrared detection signal with a high S/N ratio can be acquired.

For example, in an infrared sensor according to a seventh aspect of the present disclosure, which is the infrared sensor according to any one of the first aspect to the sixth aspect, a portion of a gate oxide film of at least one of the n-type MOSFET or the p-type MOSFET is removed.

According to this configuration, in the at least one of the p-type MOSFET or the n-type MOSFET, the gate oxide film is removed and replaced with a gas such as air or a gas such as decompressed air having a lower thermal conductivity than that of the gate oxide film, and hence it is easy to ensure the temperature difference between the hot junction and the cold junction. Thus, an infrared detection signal with a high S/N ratio can be acquired.

For example, in an infrared sensor according to an eighth aspect of the present disclosure, which is the infrared sensor according to any one of the first aspect to the seventh aspect, a voltage having a periodically repetitive waveform is applied to a gate of the n-type MOSFET and a gate of the p-type MOSFET.

According to this configuration, by performing signal processing in the frequency band of the frequency of the repetitive waveform, a noise component can be removed, and even a weak infrared detection signal can be accurately extracted.

Hereinafter, embodiments of the present disclosure will be described with reference to the drawings.

The embodiments described below are all comprehensive or specific examples. Numerical values, shapes, materials, components, the arrangement positions and connection forms of the components, steps (processes), the order of the steps (processes), and the like described in the following embodiments are mere examples, and are not intended to limit the present disclosure. Further, among the components in the following embodiments, components not included in the independent claim are described as optional components.

The drawings are schematic diagrams and are not necessarily illustrated strictly. Thus, for example, the scales and the like in the drawings are not necessarily the same. In the drawings, substantially the same configurations are denoted by the same reference signs, and redundant description thereof will be omitted or simplified.

In this specification, the terms indicating the relationship between elements such as parallel, the terms indicating the shapes of elements such as rectangular, and the numerical ranges are not expressions that indicate only the strict meanings, but are expressions that represent substantially equivalent ranges, for example, that include differences of about several percent.

In this specification, the terms “above” and “below” do not indicate the upper direction (vertically above) and the lower direction (vertically below) in absolute spatial recognition, but are used as terms defined by a relative positional relationship. Specifically, the light receiving side of an infrared sensor is defined as “above”, and the side opposite to the light receiving side is defined as “below”. The terms “above” and “below” and the like are used to designate the mutual arrangement of members, and are not intended to limit the posture of the infrared sensor during use. The terms “above” and “below” are used not only when two components are spaced apart from each other and another component is present between the two components, but also when two components are disposed in close contact with each other and the two components abut on each other.

In this specification, the term “plan view” refers to a view as seen in the direction perpendicular to the upper surface of the semiconductor substrate (in other words, the thickness direction of the semiconductor substrate), unless otherwise noted.

In this specification, ordinal numbers such as “first” and “second” do not represent the number or the order of components and are used for the purpose of distinguishing the components from each other without confusion among the components of the same kind, unless otherwise noted.

### Embodiment 1

An infrared sensor according to Embodiment 1 will be described below.

### Overall Configuration

First, an overall configuration of the infrared sensor according to Embodiment 1 will be described.

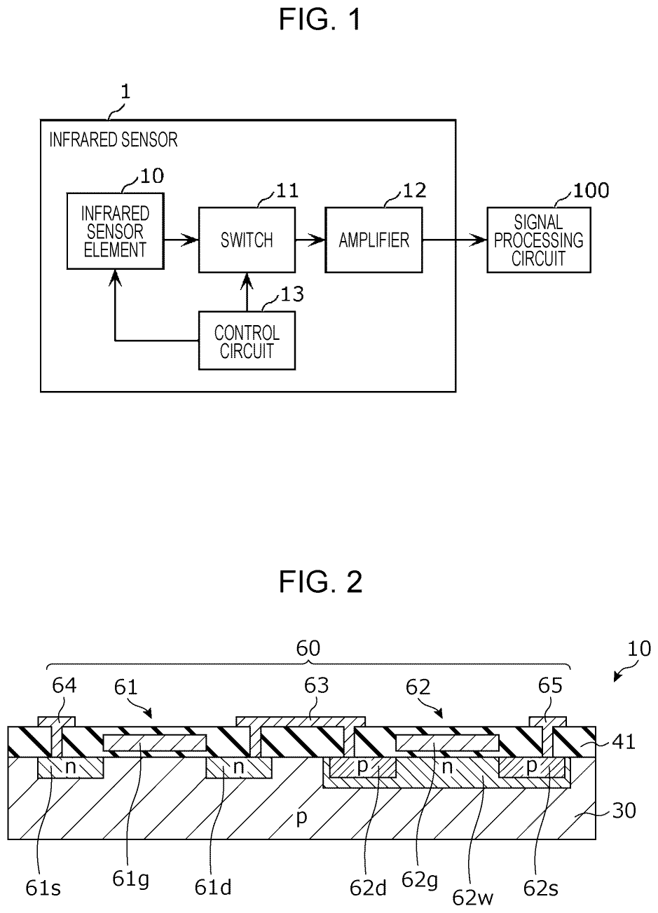

FIG. 1 is a block diagram illustrating an overall configuration of an infrared sensor 1 according to Embodiment 1.

As illustrated in FIG. 1, the infrared sensor 1 includes an infrared sensor element 10, a switch 11, an amplifier 12, and a control circuit 13. The infrared sensor 1 is, for example, an infrared sensor chip that includes a semiconductor substrate 30 (described later) and is formed on or in one semiconductor substrate 30. A portion of the infrared sensor 1 may be formed on or in another substrate. For example, at least one of the amplifier 12 or the control circuit 13 may be formed on or in a substrate different from the semiconductor substrate 30 on or in which the infrared sensor element 10 and the switch 11 are formed.

The infrared sensor element 10 generates an infrared detection signal corresponding to the amount of received infrared rays, and outputs the generated infrared detection signal. The infrared sensor element 10 is configured to be able to temporarily lose the function of generating the infrared detection signal. The infrared sensor element 10 will be described in detail later.

The switch 11 is a switch disposed on a path between the infrared sensor element 10 and the amplifier 12. The switch 11 switches between conduction and non-conduction between the infrared sensor element 10 and the amplifier 12. Alternatively, the infrared sensor 1 does not have to include the switch 11.

The amplifier 12 amplifies the infrared detection signal generated by the infrared sensor element 10. The amplifier 12 is, for example, a portion of an AFE. Although not illustrated, the infrared sensor 1 may include a filter and an AD converter included in the AFE, in addition to the amplifier 12. The amplifier 12 outputs the amplified infrared detection signal. The output from the amplifier 12 is input to, for example, a signal processing circuit 100. The output information from the amplifier 12 may be converted into digital information encoded by the AD converter.

In the present embodiment, the infrared sensor element 10 and the amplifier 12 are in a one-to-one configuration. Alternatively, the infrared sensor 1 may be an array sensor including infrared sensor elements 10 and amplifiers 12 as long as the infrared sensor elements 10 and the amplifiers 12 are in one-to-one configurations.

The control circuit 13 controls the entire infrared sensor 1. For example, the control circuit 13 outputs control signals to control whether the infrared sensor element 10 loses the function of generating the infrared detection signal and to control the operation of the switch 11. The control circuit 13 supplies, for example, control signals (for example, a high-level or low-level voltage) for controlling the infrared sensor element 10 and the switch 11 to the infrared sensor element 10 and the switch 11. The control by the control circuit 13 will be described in detail later. The control circuit 13 may output a control signal for controlling the AFE. The control circuit 13 causes the infrared sensor 1 to operate in the infrared measurement mode and the noise measurement mode, and causes the amplifier 12 to output the output information in each of the infrared measurement mode and the noise measurement mode. Alternatively, the infrared sensor 1 does not have to include the control circuit 13, and the infrared sensor 1 may be controlled by an external control device having the function of the control circuit 13.

The control circuit 13 includes, for example, one or more microcomputers or processors in which a program for performing control processing of the infrared sensor 1 is incorporated. The control circuit 13 may include a dedicated logic circuit for performing the control processing of the infrared sensor 1.

The signal processing circuit 100 performs various kinds of signal processing on the output from the amplifier 12. The signal processing circuit 100 performs, for example, processing of canceling (removing) the offset component of the amplifier 12 and the 1/f noise from the output information in the infrared measurement mode by obtaining the difference between the output information of the amplifier 12 (AFE) in the infrared measurement mode and the output information of the amplifier 12 (AFE) in the noise measurement mode.

The signal processing circuit 100 includes, for example, one or more microcomputers or processors in which a program for performing control processing is incorporated. The signal processing circuit 100 may include a dedicated logic circuit for performing the signal processing.

The signal processing circuit 100 is included in, for example, an external signal processing device, but may be included in the infrared sensor 1. When the signal processing circuit 100 is included in the infrared sensor 1, the control circuit 13 and the signal processing circuit 100 may be implemented by one microcomputer or processor, or may be implemented by one or more individual microcomputers or processors.

### Infrared Sensor Element

Next, a detailed configuration of the infrared sensor element 10 included in the infrared sensor 1 will be described.

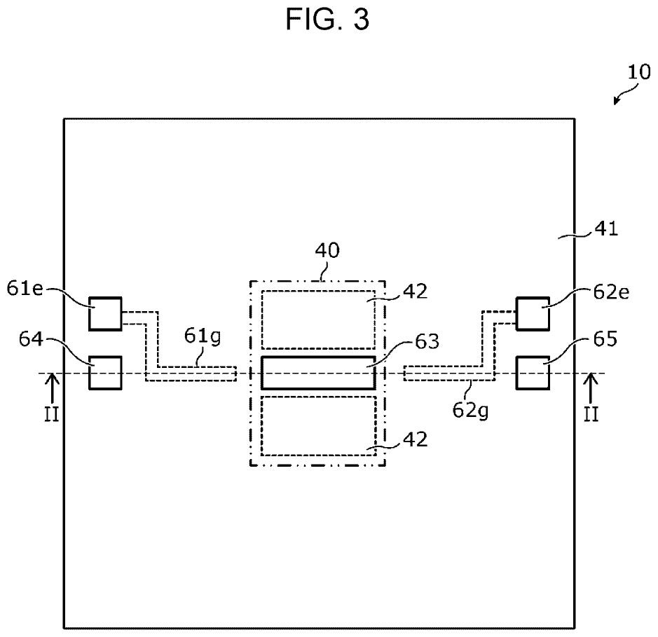

FIG. 2 is a sectional view illustrating the infrared sensor element 10 according to Embodiment 1. FIG. 3 is a plan view of the infrared sensor element 10 according to Embodiment 1 as viewed from above. FIG. 2 presents a section taken along line II-II indicated in FIG. 3. In FIG. 3, the outlines of a reflecting surface 42 and gates 61g and 62g, which are actually covered with an insulating film 41, are indicated by broken lines.

As illustrated in FIG. 2 and FIG. 3, the infrared sensor element 10 includes a light receiver 40 and a thermoelectric converter 60. The infrared sensor element 10 is formed on or in, for example, the upper surface of a semiconductor substrate 30 included in the infrared sensor 1.

The semiconductor substrate 30 is a substrate for forming the infrared sensor element 10, a peripheral circuit, and the like. The semiconductor substrate 30 is, for example, a p-type silicon substrate using single crystal silicon, but may be a semiconductor substrate other than the p-type silicon substrate, such as an n-type semiconductor substrate or a semiconductor substrate using a semiconductor material other than the single crystal silicon. The description will be given below based on that the semiconductor substrate 30 is a substrate made of a p-type semiconductor.

A reflecting surface 42, an n-type MOSFET 61, and a p-type MOSFET 62, which will be described later, are formed on or in the semiconductor substrate 30. Although not illustrated, at least one of the switch 11, the amplifier 12, a configuration of the AFE other than the amplifier 12, the control circuit 13, or the signal processing circuit 100 may be formed on or in the semiconductor substrate 30.

The thermoelectric converter 60 generates an infrared detection signal based on the heat generated by the light receiver 40. The thermoelectric converter 60 includes the n-type MOSFET 61, the p-type MOSFET 62, a hot junction metal electrode 63, a first cold junction metal electrode 64, and a second cold junction metal electrode 65.

The n-type MOSFET 61 includes a source 61s, a drain 61d, and a gate 61g. A gate oxide film is disposed between the gate 61g, which is a conductive layer, and a channel region between the source 61s and the drain 61d. The source 61s and the drain 61d of the n-type MOSFET 61 are n-type impurity regions formed by an n-type impurity being diffused into the semiconductor substrate 30. The channel region of the n-type MOSFET 61 is a portion of the semiconductor substrate 30 that is the p-type semiconductor. The channel region is a region where a channel is formed in the MOSFET. The gate 61g of the n-type MOSFET 61 is a conductive material such as polycrystal silicon. The gate 61g is connected to a metal electrode 61e disposed on the insulating film 41. The metal electrode 61e is connected to the control circuit 13 via, for example, wiring (not illustrated). A voltage from the control circuit 13 is applied to the gate 61g via the metal electrode 61e. The metal electrode 61e is made of, for example, a metal such as aluminum.

The p-type MOSFET 62 includes a source 62s, a drain 62d, a gate 62g, and a well 62w. A gate oxide film is disposed between the gate 62g, which is a conductive layer, and a channel region between the source 62s and the drain 62d. The well 62w of the p-type MOSFET 62 is an n-type impurity region formed by an n-type impurity being diffused into the semiconductor substrate 30. The source 62s and the drain 62d of the p-type MOSFET 62 are p-type impurity regions formed by a p-type impurity being diffused into the well 62w. The channel region of the p-type MOSFET 62 is a portion of the well 62w that is an n-type semiconductor. The gate 62g of the p-type MOSFET 62 is a conductive material such as polycrystal silicon. The gate 62g is connected to a metal electrode 62e disposed on the insulating film 41. The metal electrode 62e is connected to the control circuit 13 via, for example, wiring (not illustrated). A voltage from the control circuit 13 is applied to the gate 62g via the metal electrode 62e. The metal electrode 62e is made of, for example, a metal such as aluminum.

In the example illustrated in FIG. 2, the gate 61g and the gate 62g are embedded in the insulating film 41, but may be formed on the insulating film 41 when the insulating film 41 is thin.

The hot junction metal electrode 63 is located on the light receiver 40. The hot junction metal electrode 63 is not particularly limited as long as it is located at a position at which the temperature changes in synchronization with the temperature of the light receiver 40, and may be located, for example, adjacent to the light receiver 40.

The hot junction metal electrode 63 is in ohmic contact with the drain 61d of the n-type MOSFET 61 and the drain 62d of the p-type MOSFET 62. The hot junction metal electrode 63 forms a hot junction by the ohmic contact.

The first cold junction metal electrode 64 and the second cold junction metal electrode 65 are located outside the light receiver 40 in a plan view. The first cold junction metal electrode 64 and the second cold junction metal electrode 65 are disposed, for example, with the light receiver 40 interposed in a plan view.

The first cold junction metal electrode 64 is in ohmic contact with the source 61s of the n-type MOSFET 61. The first cold junction metal electrode 64 forms a cold junction by the ohmic contact.

The second cold junction metal electrode 65 is in ohmic contact with the source 62s of the p-type MOSFET 62. The second cold junction metal electrode 65 forms a cold junction by the ohmic contact.

When the n-type MOSFET 61 forms an n-type channel and the p-type MOSFET 62 forms a p-type channel, a configuration electrically connected in series to “cold junction-n-type semiconductor-hot junction-p-type semiconductor-cold junction” is formed, and the thermoelectric converter 60 can exhibit a thermoelectric conversion function. In other words, the n-type MOSFET 61 forms the n-type channel and the p-type MOSFET 62 forms the p-type channel, whereby the thermoelectric converter 60 can generate an infrared detection signal. The “thermoelectric conversion function” can be also referred to as a function of the thermoelectric converter 60 (infrared sensor element 10) generating the infrared detection signal.

Each of the hot junction metal electrode 63, the first cold junction metal electrode 64, and the second cold junction metal electrode 65 includes, for example, a metal via extending in the insulating film 41 in the thickness direction of the insulating film 41 and a metal wire disposed on the insulating film 41. The metal via is in contact with and connected to the drain 61d, the drain 62d, the source 61s, or the source 62s and the metal wire. The metal via is made of, for example, a high-melting metal such as tungsten. The metal wire is made of, for example, a metal such as aluminum.

The light receiver 40 generates heat by absorbing the infrared rays, and the temperature of the light receiver 40 increases due to the heat. The amount of heat generated by the light receiver 40 depends on the amount of infrared rays absorbed by the light receiver 40. The light receiver 40 is located above the semiconductor substrate 30. A temperature difference can be given between the hot junction and the cold junction by the temperature rise of the light receiver 40.

In the present embodiment, the light receiver 40 includes a portion of the insulating film 41 on the reflecting surface 42. In the example illustrated in FIG. 3, the light receiver 40 is a region on the semiconductor substrate 30 where the reflecting surface 42 and the hot junction metal electrode 63 are formed in a plan view. For example, reflecting surfaces 42 are formed, and the hot junction metal electrode 63 is interposed between the reflecting surfaces 42 in a plan view. The hot junction metal electrode 63 is disposed, for example, in a region including the center of the light receiver 40 in a plan view.

The insulating film 41 is disposed above the semiconductor substrate 30. The insulating film 41 is made of, for example, silicon oxide, but may be made of an insulating material (for example, silicon nitride) other than silicon oxide.

The reflecting surface 42 is, for example, the upper surface of a high-concentration impurity region of the upper surface of the semiconductor substrate 30, the high-concentration impurity region having an increased infrared reflectance by the semiconductor substrate 30 being doped with a high-concentration p-type impurity. This is a technique also described in S. Basu, B. J. Lee and M. Zhang, “Infrared Radiative Properties of Heavily Doped Silicon at Room Temperature”, Journal of Heat Transfer, Vol. 132, February 2010. For example, a silicon substrate doped with boron (B) as an impurity at a high concentration of about 10²⁰ cm⁻³ has a higher infrared reflectance than that of an undoped silicon substrate. The impurity concentration of the high-concentration impurity region is higher than that of a portion of the semiconductor substrate 30 below the high-concentration impurity region. The impurity concentration of the high-concentration impurity region is, for example, greater than or equal to 10¹⁹ cm⁻³ and less than or equal to 10²¹ cm⁻³. The multilayer structure of the reflecting surface 42 and a dielectric (here, the insulating film 41) stacked thereon is a dielectric thin film infrared absorbing structure.

When the light receiver 40 absorbs the infrared rays and the temperature of the hot junction becomes higher than that of the cold junction as a result, majority carriers gather on the cold junction side. As a result, when the n-type MOSFET 61 forms the n-type channel and the p-type MOSFET 62 forms the p-type channel, the cold junction of the n-type MOSFET 61 has a negative electromotive voltage with respect to the cold junction of the p-type MOSFET 62. In other words, a potential difference corresponding to the heat generated by the light receiver 40 is generated between the first cold junction metal electrode 64 and the second cold junction metal electrode 65. At this time, when the second cold junction metal electrode 65 is maintained at a reference potential, an infrared detection signal corresponding to the electromotive voltage is output from the first cold junction metal electrode 64. The temperature relationship between the “hot junction” and the “cold junction” of the thermoelectric converter 60 is not necessarily such that the temperature of the hot junction is higher than the temperature of the cold junction. For example, when the infrared sensor 1 is used to detect the temperature of an object lower than the temperature of the infrared sensor 1 itself, the temperature of the hot junction may be lower than the temperature of the cold junction. At this time, the polarity of the electromotive voltage of the thermoelectric converter 60 is inverted.

Such an infrared sensor element 10 can be manufactured, for example, by using a processing process used for manufacturing a semiconductor device.

### Operations

Next, operations of the infrared sensor 1 according to the present embodiment will be described.

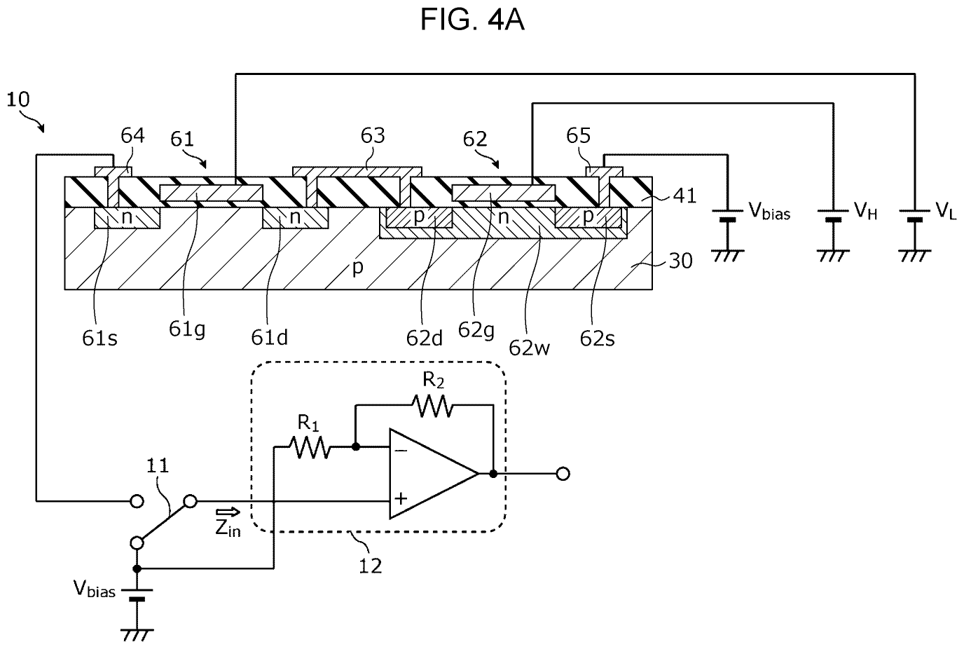

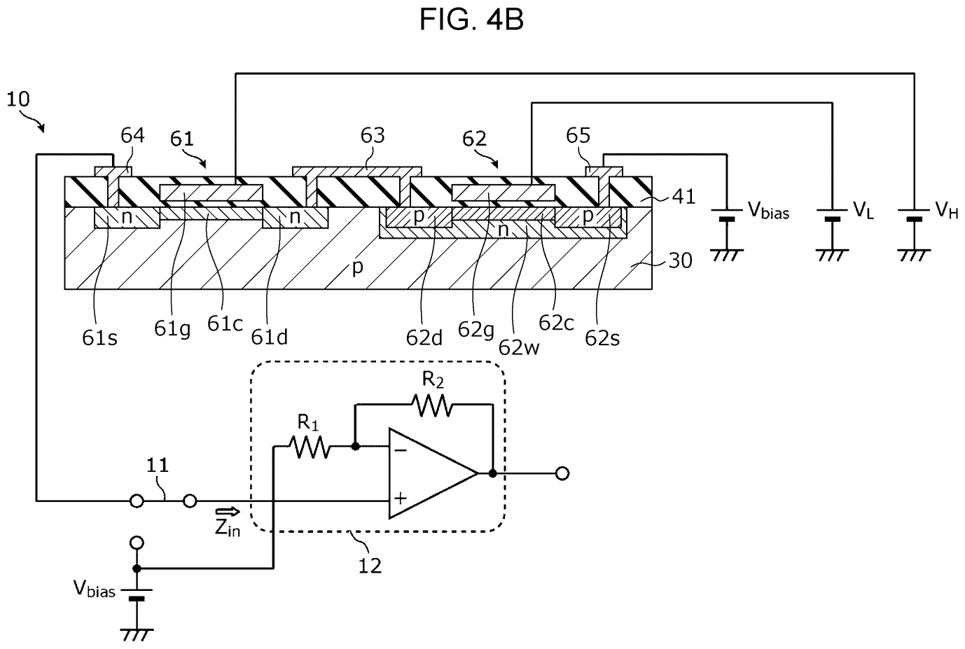

FIG. 4A is a diagram for explaining an operation in the noise measurement mode of the infrared sensor 1 according to Embodiment 1. FIG. 4B is a diagram for explaining an operation in the infrared measurement mode of the infrared sensor 1 according to Embodiment 1. In FIG. 4A and FIG. 4B, a section of the infrared sensor element 10 and a general circuit configuration of the switch 11, the amplifier 12, and the wiring and the like connected to the infrared sensor element 10 are schematically illustrated.

As illustrated in FIG. 4A and FIG. 4B, a bias voltage V_{bias} is applied to the second cold junction metal electrode 65 connected to the source 62s of the p-type MOSFET 62. The first cold junction metal electrode 64 connected to the source 61s of the n-type MOSFET 61 is connected to the input terminal of the amplifier 12 via the switch 11. The infrared detection signal generated by the infrared sensor element 10 is output from the first cold junction metal electrode 64 to the amplifier 12.

The amplifier 12 is, for example, a voltage-input amplifier having a high input impedance. In the illustrated example, the amplifier 12 is a voltage-input voltage-output voltage amplifier. The voltage amplifier includes, for example, a non-inverting amplifier circuit using an operational amplifier. In the illustrated example, the non-inverting input terminal of the operational amplifier is connected to the switch 11, and the inverting input terminal of the operational amplifier is connected to a bias voltage V_{bias} via a resistance R₁ and to the output terminal of the operational amplifier via a resistance R₂. A voltage gain G of the non-inverting amplifier circuit is 1+(R₂/R₁) due to the resistance R₁ and the resistance R₂ of the voltage amplifier. For an input impedance Zᵢₙ of the amplifier 12, Zᵢₙ=Rᵢ·A₀/G is established, where Rᵢ is an input resistance between the two input terminals of the operational amplifier, and A₀ is an open loop gain. For example, when Rᵢ=100 MΩ, A₀=120 dB, and G=1000, Zᵢₙ=100 GΩ is established, and hence the input impedance of the amplifier 12 is very high. The amplifier 12 is not particularly limited. For example, an active element having a high input impedance may be used for the amplifier 12, and the amplifier 12 may be a transconductance amplifier (a voltage-input current-output amplifier) or a voltage follower (an amplifier having an amplification factor of 1).

The switch 11 is provided in a stage preceding the input terminal of the amplifier 12. The switch 11 is connected to the infrared sensor element 10 and the amplifier 12 so as to be able to interrupt the transmission of the infrared detection signal from the infrared sensor element 10 to the amplifier 12. The switch 11 is, for example, a single-pole double-throw (SPDT) switch. The switch 11 can switch the connection destination of the input terminal of the amplifier 12 between the first cold junction metal electrode 64 and the bias voltage V_{bias}. The switch 11 corresponds to the above-described measurement mode changeover switch. The switch 11 may be a mechanical switch, but is, for example, a semiconductor switch in view of compatibility with the semiconductor manufacturing process of producing the infrared sensor 1. In general, the semiconductor switch is inferior to the mechanical switch in isolation in the closed state. In this specification, “interruption” and “non-conduction” in a switch are expressions that indicate substantially an interrupted state and a non-conductive state, and include a case where a signal leaks without being in a completely interrupted state and a completely non-conductive state.

First, the operation of the infrared sensor 1 in the noise measurement mode will be described. As illustrated in FIG. 4A, in the noise measurement mode, the switch 11 connects the bias voltage V_{bias} to the input terminal of the amplifier 12. In the noise measurement mode, a gate voltage V_{L} at which the n-type MOSFET 61 does not form an n-type channel is applied to the gate 61g of the n-type MOSFET 61 by the control circuit 13. In the noise measurement mode, a gate voltage V_{H} at which the p-type MOSFET 62 does not form a p-type channel is applied to the gate 62g of the p-type MOSFET 62 by the control circuit 13. As specific examples of the gate voltage V_{L} and the gate voltage V_{H}, the gate voltage V_{L} is at a GND level, and the gate voltage V_{H} is 2V_{bias}. Alternatively, the gate voltages may be applied so that a channel is not formed in only one of the n-type MOSFET 61 and the p-type MOSFET 62.

As a result of such an operation, since no channel is formed in the n-type MOSFET 61 and the p-type MOSFET 62 of the infrared sensor element 10, the configuration electrically connected in series to “cold junction-n-type semiconductor-hot junction-p-type semiconductor-cold junction” is not formed, and the thermoelectric conversion function of the thermoelectric converter 60 is not exhibited. Thus, even when the isolation of the switch 11 is poor, the infrared detection signal is not transmitted to the amplifier 12. In the example illustrated in FIG. 4A, the bias voltage V_{bias} is applied to both of the differential input terminals of the operational amplifier of the amplifier 12, and hence the input to the amplifier 12 is in the state of zero. As a result, the offset component generated in the amplifier 12 and the 1/f noise appear in the output of the amplifier 12. These noise components are, for example, encoded by the AD converter and output as digital information to the signal processing circuit 100. The output digital information of the noise measurement mode is stored in the signal processing circuit 100.

Next, the operation of the infrared sensor 1 in the infrared measurement mode will be described. As illustrated in FIG. 4B, in the infrared measurement mode, the switch 11 connects the first cold junction metal electrode 64 to the input terminal of the amplifier 12. In the infrared measurement mode, the gate voltage V_{H} at which the n-type MOSFET 61 forms an n-type channel 61c is applied to the gate 61g of the n-type MOSFET 61 by the control circuit 13. In the infrared measurement mode, the gate voltage V_{L} at which the p-type MOSFET 62 forms a p-type channel 62c is applied to the gate 62g of the p-type MOSFET 62 by the control circuit 13. The value of the gate voltage V_{L} applied to the gate 61g in the noise measurement mode may be different from the value of the gate voltage V_{L} applied to the gate 62g in the infrared measurement mode. The value of the gate voltage V_{H} applied to the gate 62g in the noise measurement mode may be different from the value of the gate voltage V_{H} applied to the gate 61g in the infrared measurement mode.

As a result of such an operation, the channels are formed in the n-type MOSFET 61 and the p-type MOSFET 62 of the infrared sensor element 10, and the configuration electrically connected to “cold junction-n-type semiconductor-hot junction-p-type semiconductor-cold junction” is formed, and the thermoelectric conversion function of the thermoelectric converter 60 is exhibited. The infrared detection signal generated by the thermoelectric conversion function flows out as majority carriers (electrons) of the n-type MOSFET 61 from the first cold junction metal electrode 64 connected to the n-type MOSFET 61, and is input to the amplifier 12. The output information of the amplifier 12 is information with the offset component generated in the amplifier 12 and the 1/f noise added to the infrared information. The output information is, for example, encoded by the AD converter and output as digital information to the signal processing circuit 100. The digital information output in the infrared measurement mode is stored in the signal processing circuit 100.

Finally, when the output of the amplifier 12 in the noise measurement mode is subtracted from the output of the amplifier 12 in the infrared measurement mode, infrared information in which the offset component generated in the amplifier 12 and the 1/f noise have been removed is obtained. This calculation is performed by, for example, the signal processing circuit 100.

While the gate 61g and the gate 62g are illustrated as being applied with the voltages individually in FIG. 4A and FIG. 4B, a voltage conversion circuit may be provided between the control circuit 13 and one of the gate 61g and the gate 62g, and the control circuit 13 may supply voltages to the gate 61g and the gate 62g at once.

As described above, in the infrared sensor 1, the thermoelectric converter 60 includes the n-type MOSFET 61 and the p-type MOSFET 62. Accordingly, depending on whether the n-type MOSFET 61 and the p-type MOSFET 62 form the channels, whether the series connection configuration of “cold junction-n-type semiconductor-hot junction-p-type semiconductor-cold junction” is formed is determined, and whether the thermoelectric conversion function of the thermoelectric converter 60 is exhibited can be controlled. Thus, when it is not desired to input the infrared detection signal to the amplifier 12, it is possible not to exhibit the thermoelectric conversion function of the thermoelectric converter 60. Accordingly, the leakage of the infrared detection signal as in the case of interrupting the infrared detection signal by the semiconductor switch is not generated. As a result, for example, in the noise measurement mode, the offset component of the amplifier 12 and the 1/f noise can be measured without being affected by the leakage of the infrared detection signal from the infrared sensor element 10. Thus, the offset component of the amplifier 12 and the 1/f noise can be effectively removed from the output in the infrared measurement mode, and hence the infrared sensor 1 can increase the detection accuracy of infrared rays.

The infrared sensor 1 includes the amplifier 12, and the amplifier 12 is the voltage-input amplifier. By using such a voltage-input amplifier having the high input impedance Zᵢₙ, the current flowing through the infrared sensor element 10 in the infrared sensor 1 can be regarded as the same in the noise measurement mode and the infrared measurement mode. Specifically, in the noise measurement mode, the infrared sensor 1 does not cause the thermoelectric conversion function of the thermoelectric converter 60 to be exhibited, and hence the current flowing out from the infrared sensor element 10 is zero. In the infrared measurement mode, the infrared sensor 1 causes the thermoelectric conversion function of the thermoelectric converter 60 to be exhibited, and hence an electromotive voltage is generated in the thermoelectric converter 60. However, since the input impedance Zᵢₙ of the amplifier 12 is high, a current hardly flows from the infrared sensor element 10, and the current is close to zero.

The current flowing inside the thermoelectric converter 60 by the thermoelectric conversion function acts in a direction of eliminating the temperature difference between the hot junction and the cold junction due to the Peltier effect opposite to the Seebeck effect. In other words, when the amount of current flowing inside the thermoelectric converter 60 changes, the temperature distribution between the hot junction and the cold junction is disturbed. However, as described above, in the infrared sensor 1, the current is zero or close to zero in both of the noise measurement mode and the infrared measurement mode, and can be regarded as the same. Thus, even when the switch 11 is switched so as to shift the measurement mode from the noise measurement mode to the infrared measurement mode, a phenomenon in which the temperature distribution between the hot junction and the cold junction is disturbed once by the change in the amount of current after the switching and is redistributed with time does not occur. That is, when the measurement mode is switched from the noise measurement mode to the infrared measurement mode, it is possible to maintain the detection accuracy of infrared rays even when the output information from the amplifier 12 of the infrared sensor 1 is read without waiting for the time required for the temperature distribution between the hot junction and the cold junction to be redistributed and settled in a steady state.

On the other hand, when the amplifier 12 is a current-input amplifier (for example, a transimpedance amplifier) having an input impedance close to zero, a current having a value obtained by dividing the electromotive voltage by the internal resistance of the thermoelectric converter 60 starts to flow in the thermoelectric converter 60 from the moment when the measurement mode has been switched from the noise measurement mode to the infrared measurement mode, and the temperature distribution between the hot junction and the cold junction is redistributed. The output information from the amplifier 12 read without waiting for the time required for the redistribution may include an error. However, in the case where the amplifier 12 is used for the purpose capable of ensuring the time for switching from the noise measurement mode to the infrared measurement mode, there is no problem even though the amplifier 12 is the current-input amplifier.

### Embodiment 2

Next, an infrared sensor according to Embodiment 2 will be described. The infrared sensor according to Embodiment 1 has the configuration in which one amplifier is provided for one infrared sensor, but in Embodiment 2, a configuration in which one amplifier is provided for infrared sensors will be described. In the following description, points different from Embodiment 1 will be mainly described, and description of common points will be omitted or simplified.

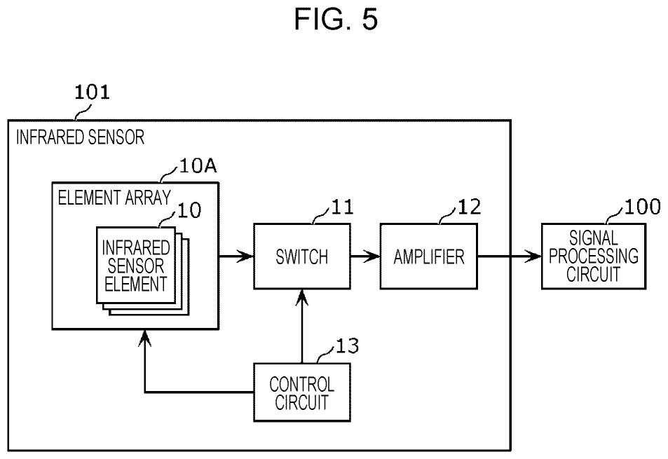

FIG. 5 is a block diagram illustrating an overall configuration of an infrared sensor 101 according to Embodiment 2.

As illustrated in FIG. 5, the infrared sensor 101 according to the present embodiment is different in that the infrared sensor 101 includes an element array 10A including infrared sensor elements 10 instead of the infrared sensor element 10. The infrared sensor 101 is, for example, an infrared image sensor (infrared imaging device) in which the infrared sensor elements 10 are arranged as pixels.

The element array 10A includes the infrared sensor elements 10 arranged in an array on the common semiconductor substrate 30. In the block diagram of FIG. 5, the infrared sensor elements 10 are illustrated in an overlapping manner for convenience, but actually, the infrared sensor elements 10 are arranged in an array form in which the infrared sensor elements 10 are arranged in rows in the lengthwise direction and the widthwise direction in a plan view. Each of the infrared sensor elements 10 generates an infrared detection signal corresponding to the amount of received infrared rays, and outputs the generated infrared detection signal. Each of the infrared sensor elements 10 is connected to the amplifier 12 via the switch 11. In the present embodiment, the number of infrared sensor elements 10 is N (N is an integer greater than or equal to 2).

When the element array 10A includes the N infrared sensor elements 10, the infrared sensor elements 10 and the amplifier 12 are in an N-to-1 configuration. According to the N-to-1 configuration, in an array sensor in which N infrared sensors are arranged in an array, it is not necessary to provide N amplifiers 12 having a large amount of current consumption, and it is effective for power saving. In this case, at least one of the infrared sensor elements 10 is sequentially allocated to one amplifier 12 in a time division manner. Thus, a certain time is required for scanning the pixels by sequentially switching the infrared sensor elements 10 that output the infrared detection signals, but from the viewpoint of the current consumption of the amplifier 12, it is desirable to connect the infrared sensor elements 10 and the amplifier 12 in a many-to-one configuration within a range capable of ensuring the number of imaging frames required for one second.

Alternatively, the infrared sensor elements 10 and the amplifier 12 are not limited to the N-to-1 configuration, and the infrared sensor 101 may include amplifiers 12. In this case, for example, the amplifier 12 is provided for each pixel row, each pixel column, or each pixel block.

Next, operations of the infrared sensor 101 according to the present embodiment will be described.

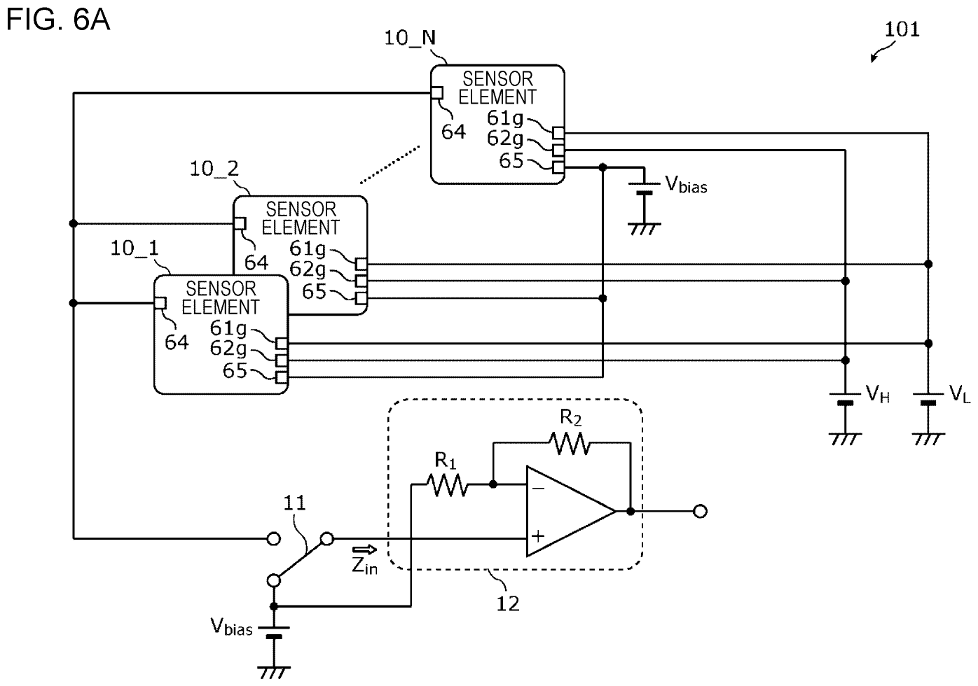

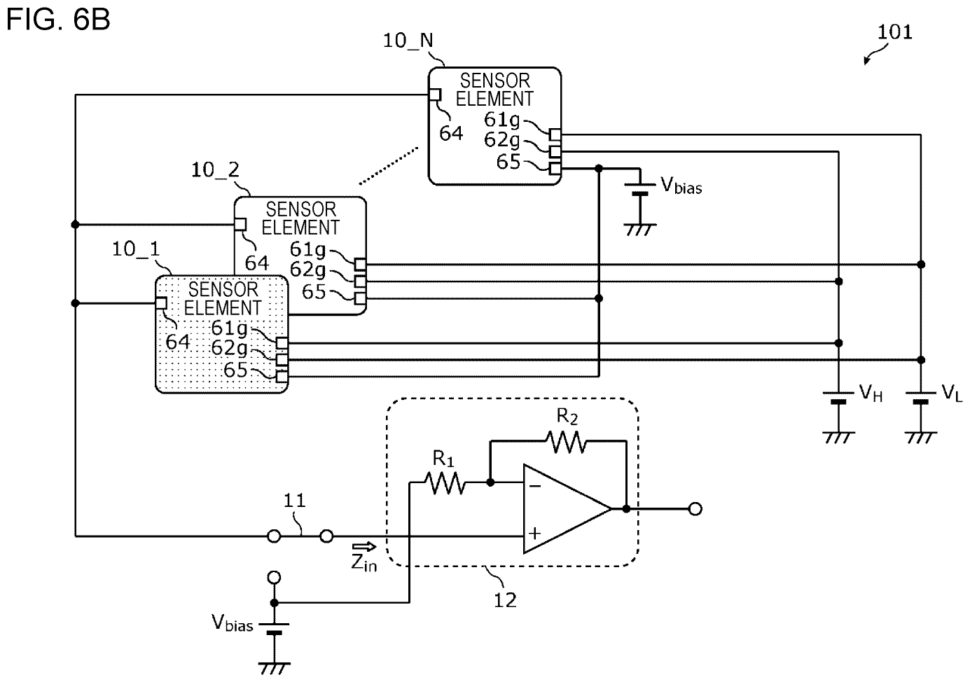

FIG. 6A is a diagram for explaining an operation in the noise measurement mode of the infrared sensor 101 according to Embodiment 2. FIG. 6B is a diagram for explaining an operation in the infrared measurement mode of the infrared sensor 101 according to Embodiment 2. In FIG. 6A and FIG. 6B, the infrared sensor elements 10 are denoted by reference signs of infrared sensor elements 10_1 to 10_N for distinction. In FIG. 6A and FIG. 6B, each of the infrared sensor elements 10 (expressed as “sensor elements” in the drawings) is schematically illustrated as a block including four terminals, that is, the first cold junction metal electrode 64, the second cold junction metal electrode 65, the gate 61g, and the gate 62g. The first cold junction metal electrode 64 is a terminal connected to the source 61s of the n-type MOSFET 61. The second cold junction metal electrode 65 is a terminal connected to the source 62s of the p-type MOSFET 62.

The first cold junction metal electrodes 64 connected to the respective n-type MOSFETs 61 of the infrared sensor elements 10_1 to 10_N are connected in parallel and connected to the input terminal of the amplifier 12 via the switch 11. A bias voltage V_{bias} is applied to the second cold junction metal electrodes 65 connected to the respective p-type MOSFETs 62 of the infrared sensor elements 10_1 to 10_N. FIG. 6B illustrates a case where only the infrared sensor element 10_1 is selected from the infrared sensor elements 10_1 to 10_N and outputs the infrared detection signal. In other words, in FIG. 6B, the selected pixel is the infrared sensor element 10_1, and the non-selected pixels are the infrared sensor elements 10_2 to 10_N. In FIG. 6B, the selected infrared sensor element 10_1 is marked with dots.

In the noise measurement mode, as illustrated in FIG. 6A, a gate voltage V_{L} is applied to the gate 61g of the n-type MOSFET 61 by the control circuit 13, and a gate voltage V_{H} is applied to the gate 62g of the p-type MOSFET 62 by the control circuit 13 in each of the infrared sensor elements 10_1 to 10_N so that the thermoelectric conversion function is not exhibited in all the infrared sensor elements 10_1 to 10_N. In the noise measurement mode, the switch 11 connects a bias voltage V_{bias} to the input terminal of the amplifier 12. Since the thermoelectric conversion function is not exhibited in all the infrared sensor elements 10_1 to 10_N, even when the isolation of the switch 11 is poor, the N infrared detection signals are not transmitted to the amplifier 12. In the example illustrated in FIG. 6A, the bias voltage V_{bias} is applied to both of the differential input terminals of the operational amplifier of the amplifier 12, and hence the input to the amplifier 12 is in the state of zero. As a result, the offset component generated in the amplifier 12 and the 1/f noise appear in the output of the amplifier 12. These noise components are, for example, encoded by the AD converter and output as digital information to the signal processing circuit 100. The output digital information of the noise measurement mode is stored in the signal processing circuit 100.

Next, in the infrared measurement mode, as illustrated in FIG. 6B, only the partial infrared sensor element 10_1 of the N infrared sensor elements 10_1 to 10_N is selected and outputs the infrared detection signal, and all the other infrared sensor elements 10_2 to 10_N are not selected and do not output the infrared detection signals.

Specifically, in the example illustrated in FIG. 6B, since the infrared sensor element 10_1 is selected, the gate voltage V_{H} is applied to the gate 61g of the n-type MOSFET 61 by the control circuit 13, and the gate voltage V_{L} is applied to the gate 62g of the p-type MOSFET 62 by the control circuit 13 in the infrared sensor element 10_1 so that the n-type MOSFET 61 and the p-type MOSFET 62 of only the infrared sensor element 10_1 form the channels to exhibit the thermoelectric conversion function. The gate voltage V_{L} is applied to the gate 61g of the n-type MOSFET 61 by the control circuit 13, and the gate voltage V_{H} is applied to the gate 62g of the p-type MOSFET 62 by the control circuit 13 in each of the infrared sensor elements 10_2 to 10_N so that the n-type MOSFET 61 and the p-type MOSFET 62 of each of the unselected infrared sensor elements 10_2 to 10_N do not form the channels and do not exhibit the thermoelectric conversion function. In the infrared measurement mode, the switch 11 connects the first cold junction metal electrode connected to the n-type MOSFET 61 to the input terminal of the amplifier 12. The infrared detection signal of the infrared sensor element 10_1 flows out as majority carriers (electrons) of the n-type MOSFET 61 from the first cold junction metal electrode 64 connected to the n-type MOSFET 61, and is input to the amplifier 12. The output information of the amplifier 12 is information with the offset component generated in the amplifier 12 and the 1/f noise added to the infrared information of the infrared sensor element 10_1. The output information is, for example, encoded by the AD converter and output as digital information to the signal processing circuit 100. The digital information corresponding to the infrared sensor element 10_1 output in the infrared measurement mode is stored in the signal processing circuit 100.

In FIG. 6A and FIG. 6B, the voltages to be applied to the gate 61g and the gate 62g are switched by changing the position of the wiring connected to the gate 61g and the gate 62g in the infrared sensor element 10_1, but actually, the position of the wiring is not changed. Actually, for example, the voltages to be applied to the gate 61g and the gate 62g are switched by switching a switch, or connecting a control line to each of the gate 61g and the gate 62g of each of the infrared sensor elements 10_1 to 10_N and applying voltages individually, or the like.

Finally, when the output of the amplifier 12 in the noise measurement mode is subtracted from the output of the amplifier 12 corresponding to the infrared sensor element 10_1 in the infrared measurement mode, infrared information of the infrared sensor element 10_1 in which the offset component generated in the amplifier 12 and the 1/f noise have been removed is obtained. This calculation is performed by, for example, the signal processing circuit 100. When the infrared sensor element 10_1 is selected, the thermoelectric conversion function is not exhibited in the infrared sensor elements 10_2 to 10_N, and hence the infrared detection signals of the infrared sensor elements 10_2 to 10_N do not leak and mix as noise of the infrared detection signal of the infrared sensor element 10_1. Thus, since an error in detection of infrared rays in the infrared measurement mode can be reduced, the infrared sensor 101 can increase the detection accuracy of infrared rays.

In the infrared measurement mode, an operation similar to that of the infrared sensor element 10_1 is sequentially performed for each of the infrared sensor elements 10_1 to 10_N, and infrared information of each of the infrared sensor elements 10_1 to 10_N can be obtained.

### Embodiment 3

Next, an infrared sensor according to Embodiment 3 will be described. In the following description, points different from Embodiments 1 and 2 will be mainly described, and description of common points will be omitted or simplified.

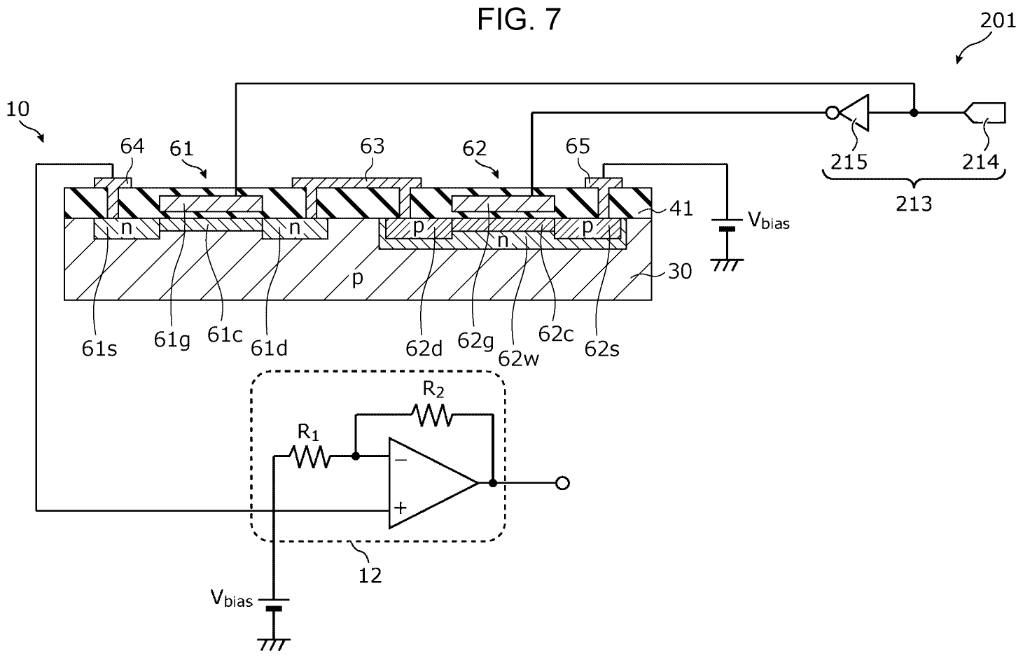

FIG. 7 is a diagram illustrating a configuration of an infrared sensor 201 according to Embodiment 3. FIG. 7 schematically illustrates a section of the infrared sensor element 10 and a general circuit configuration of the amplifier 12 and a control circuit 213.

As illustrated in FIG. 7, the infrared sensor 201 according to the present embodiment is different from the infrared sensor 1 according to Embodiment 1 in that the infrared sensor 201 does not include the switch 11 and includes the control circuit 213 instead of the control circuit 13.

In the infrared sensor 201, the first cold junction metal electrode 64 connected to the source 61s of the n-type MOSFET 61 is connected to the input terminal of the amplifier 12 not via a switch.

The control circuit 213 includes a voltage supply circuit 214 and an inverter 215. The control circuit 213 may further include a microcomputer, a processor, or a logic circuit, similarly to the control circuit 13.

The voltage supply circuit 214 supplies a voltage having a periodically repetitive waveform to the infrared sensor element 10. The voltage supply circuit 214 is connected to the gate 61g of the n-type MOSFET 61 and the gate 62g of the p-type MOSFET 62. In the example illustrated in FIG. 7, the voltage supply circuit 214 is connected to the gate 61g not via the inverter 215, and is connected to the gate 62g via the inverter 215.

The inverter 215 modulates, specifically inverts, the waveform of the voltage supplied from the voltage supply circuit 214. The inverter 215 is disposed between the voltage supply circuit 214 and the gate 62g. A voltage having a waveform inverted from that of the voltage to be applied to the gate 61g is applied to the gate 62g. Alternatively, the inverter 215 may be disposed between the voltage supply circuit 214 and the gate 61g instead of between the voltage supply circuit 214 and the gate 62g. The control circuit 213 does not have to include the inverter 215, and two voltage supply circuits 214 may individually apply voltages having different waveforms, that is, voltages having inverted waveforms, to the gate 61g and the gate 62g.

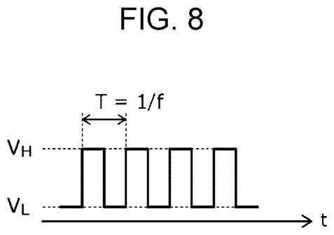

FIG. 8 is a diagram illustrating an example of a waveform of a voltage output from the voltage supply circuit 214. In the infrared sensor 201, the switch provided between the input terminal of the amplifier 12 and the infrared sensor element 10 can be omitted and the noise measurement mode can be omitted by using the fact that the exhibition of the thermoelectric conversion function can be controlled by the control signals (voltages) applied to the gate 61g of the n-type MOSFET 61 and the gate 62g of the p-type MOSFET 62.

Specifically, a voltage having a periodically repetitive waveform, for example, a pulse voltage (to the gate 62g, a voltage having a waveform inverted from that of FIG. 8) having a frequency f (period T) as illustrated in FIG. 8 is applied to the gate 61g of the n-type MOSFET 61 and the gate 62g of the p-type MOSFET 62. In the example illustrated in FIG. 8, the voltage value of the pulse voltage is a gate voltage V_{L} at a low level and a gate voltage V_{H} at a high level. Since one inverter 215 is inserted between the gate 62g and the voltage supply circuit 214, when the gate voltage V_{H} is applied to the gate 61g of the n-type MOSFET 61, the gate voltage V_{L} is applied to the gate 62g of the p-type MOSFET 62. As a result, the thermoelectric conversion function is exhibited in the infrared sensor element 10. In contrast, when the gate voltage V_{L} is applied to the gate 61g of the n-type MOSFET 61, the gate voltage V_{H} is applied to the gate 62g of the p-type MOSFET 62. As a result, the thermoelectric conversion function is lost and is not exhibited in the infrared sensor element 10. The exhibition and loss of the thermoelectric conversion function are repeated at the frequency f.

Since the exhibition and loss of the thermoelectric conversion function can be followed even when the frequency f is in the order of kilohertz, infrared information in which the 1/f noise and the offset component of the amplifier 12 have been removed can be obtained by measuring the crest value of the output of the amplifier 12 in the frequency region of the order of kilohertz in which the 1/f noise is sufficiently attenuated in the amplifier 12. The crest value may be read by reading the peak-to-peak value through a narrow band-pass filter having a transmission center frequency at the frequency f, or by performing synchronous detection using a pulse of the frequency f as a reference signal.

As described above, in the infrared sensor 201, the voltage having the periodically repetitive waveform is applied to the gate 61g of the n-type MOSFET 61 and the gate 62g of the p-type MOSFET 62. Accordingly, since the noise component can be removed by performing the signal processing with the frequency band of the repetitive frequency, even a weak infrared detection signal can be accurately extracted.

### Embodiment 4

Next, an infrared sensor according to Embodiment 4 will be described. In Embodiment 4, a configuration in which a light receiver is supported in midair will be described. In the following description, points different from Embodiments 1 to 3 will be mainly described, and description of common points will be omitted or simplified.

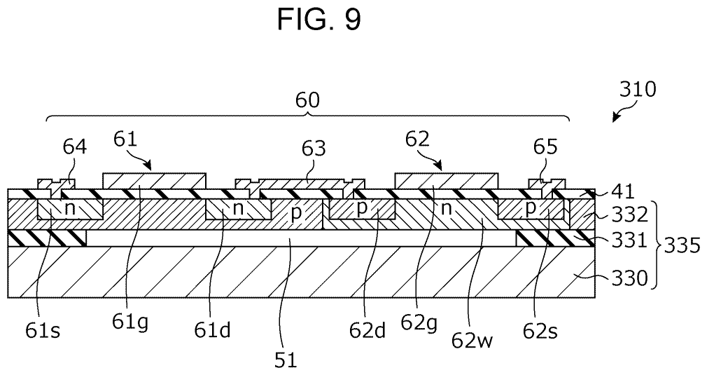

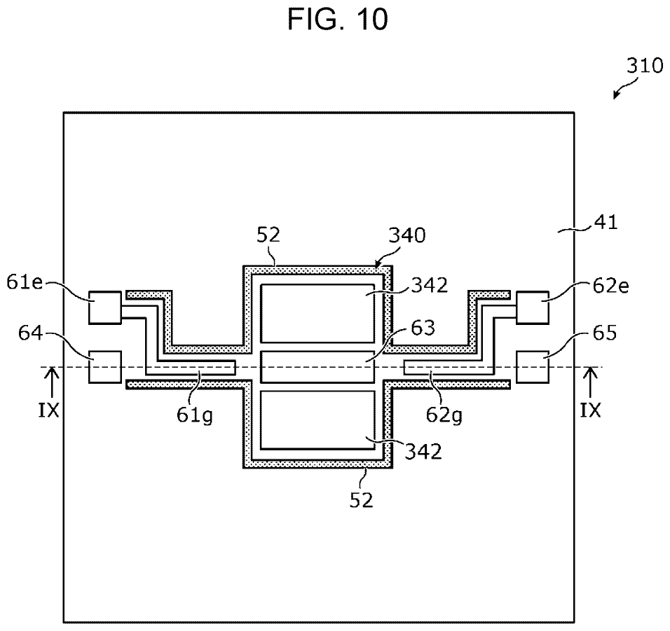

FIG. 9 is a sectional view illustrating an infrared sensor element 310 according to Embodiment 4. FIG. 10 is a plan view of the infrared sensor element 310 according to Embodiment 4 as viewed from above. FIG. 9 presents a section taken along line IX-IX indicated in FIG. 10. In FIG. 10, for ease of viewing, the regions where slits 52 are formed are marked with dots.

The infrared sensor according to the present embodiment has a configuration in which the infrared sensor element 10 of the infrared sensor according to any one of Embodiments 1 to 3 has been changed to the infrared sensor element 310.

The infrared sensor element 310 according to the present embodiment is different from the infrared sensor element 10 according to any one of Embodiments 1 to 3 in that the infrared sensor element 310 is formed on or in a multilayer substrate 335 instead of the semiconductor substrate 30, that the infrared sensor element 310 includes a light receiver 340 instead of the light receiver 40, and that a gap 51 and slits 52 are formed.

As illustrated in FIG. 9 and FIG. 10, the infrared sensor element 310 is formed using the multilayer substrate 335 included in the infrared sensor according to the present embodiment. In the example illustrated in FIG. 9, the multilayer substrate 335 is a three-layer substrate in which a semiconductor substrate 330, an embedded oxide film layer 331, and a semiconductor layer 332 are stacked in this order from the lower side. The multilayer substrate 335 is, for example, a silicon on insulator (SOI) substrate. Alternatively, the multilayer substrate 335 may be a multilayer substrate other than the SOI substrate. The description will be given below based on that the multilayer substrate 335 is the SOI substrate.

The semiconductor substrate 330 is an example of a substrate and is made of, for example, single crystal silicon. Although not illustrated, the semiconductor substrate 330 includes the reflecting surface 42 having an increased infrared reflectance by being doped with a high-concentration p-type impurity, similarly to the semiconductor substrate 30. The oxide film layer 331 is made of, for example, silicon oxide at a position overlapping a metal film 342 in a plan view. The semiconductor layer 332 is, for example, an SOI layer, and is a p-type silicon layer using single crystal silicon.

The n-type MOSFET 61 and the p-type MOSFET 62 formed on or in the semiconductor substrate 30 in the infrared sensor element 10 are formed on or in the p-type semiconductor layer 332 in the infrared sensor element 310. Thus, the thermoelectric converter 60 including the n-type MOSFET 61 and the p-type MOSFET 62 is located above the semiconductor substrate 330. In the infrared sensor element 310, the n-type MOSFET 61 and the p-type MOSFET 62 also function as arms that couple the light receiver 340 and the multilayer substrate 335 and support the light receiver 340 in midair. In the infrared sensor element 310, a portion of the insulating film 41 is disposed as a gate oxide film of the n-type MOSFET 61 and the p-type MOSFET 62. In the infrared sensor element 310, the hot junction metal electrode 63, the first cold junction metal electrode 64, and the second cold junction metal electrode 65 are entirely made of, for example, aluminum.

In the present embodiment, the oxide film layer 331 below the n-type MOSFET 61, the hot junction metal electrode 63, and the p-type MOSFET 62 is removed, and the gap 51 is formed between the n-type MOSFET 61, the p-type MOSFET 62, and the light receiver 340, and the semiconductor substrate 330. The gap 51 is filled with a gas such as air or a gas such as decompressed air. For example, the gap 51 overlaps the light receiver 340, the hot junction metal electrode 63, the gate 61g, and the gate 62g, and does not overlap the first cold junction metal electrode 64 and the second cold junction metal electrode 65 in a plan view. The first cold junction metal electrode 64 and the second cold junction metal electrode 65 are located outside the gap 51 in a plan view.

The slits 52 are regions where the semiconductor layer 332 and the insulating film 41 on the semiconductor layer 332 have been removed at once by, for example, dry etching. The slits 52 are formed such that the light receiver 340, and the gate 61g and the gate 62g on the insulating film 41 are interposed in a plan view.

The oxide film layer 331 is partially etched through the slits 52, thereby forming the gap 51. Thus, the slits 52 and the gap 51 are connected to each other. For example, hydrofluoric acid is used for the etching for forming the gap 51. The oxide film layer 331 and the insulating film 41 on the semiconductor layer 332 are eroded by the hydrofluoric acid, but in order to provide an area of the oxide film layer 331 and the insulating film 41 which is not eroded, it is effective to apply a method of coating and protecting with a photoresist as disclosed in D. Kobayashi, C.-J. Kim and H. Fujita, “Photoresist-Assisted Release of Movable Microstructures”, Jpn. J. Appl. Phys. Vol. 32 (1993) pp. L1642-L1644. For example, in a plan view, the gap 51 is formed in a region interposed between the slits 52.

The light receiver 340 is located above the semiconductor substrate 330. In the present embodiment, the light receiver 340 includes the insulating film 41 and the metal film 342 on the insulating film 41. In the example illustrated in FIG. 10, the light receiver 340 is a region where the metal film 342 and the hot junction metal electrode 63 are formed on the insulating film 41 above the semiconductor substrate 330 in a plan view.

The metal film 342 is located in the vicinity of the hot junction metal electrode 63 on the insulating film 41 in a plan view. The light receiver 340 includes, for example, metal films 342, and the hot junction metal electrode 63 is interposed between the metal films 342 in a plan view. The hot junction metal electrode 63 is disposed, for example, in a region including the center of the light receiver 340 in a plan view. The metal films 342 overlap the reflecting surface 42 in a plan view. The metal films 342 absorb at least a portion of the infrared rays radiated on the infrared sensor element 310. The metal films 342 are made of, for example, titanium, titanium nitride, tungsten, or the like.

In the light receiver 340, the multilayer structure including the metal films 342, the insulating film 41 below the metal films 342, the semiconductor layer 332 below the insulating film 41, the gap 51 below the semiconductor layer 332, and the reflecting surface 42 below the gap 51 forms an infrared interference absorbing structure. Since the heat generated in the metal films 342 that have absorbed the infrared rays is unlikely to escape to the surrounding air or the decompressed air, the formation of the gap 51 makes it easy to ensure the temperature difference between the hot junction and the cold junction. Thus, by using the infrared sensor element 310, an infrared detection signal with a high S/N ratio can be acquired. This effect is higher as the pressure in the gap 51 is lower.

As described above, in the infrared sensor element 310, the n-type MOSFET 61 and the p-type MOSFET 62 support the light receiver 340 in midair, and the gap 51 is formed, thereby ensuring the temperature difference between the hot junction and the cold junction. Thus, by decreasing the thermal conductivity of the n-type MOSFET 61 and the p-type MOSFET 62 located between the hot junction and the cold junction, it becomes easier to ensure the temperature difference between the hot junction and the cold junction. For example, the thermal conductivity of the n-type MOSFET 61 and the p-type MOSFET 62 can be decreased by removing a portion of the gate oxide film of the n-type MOSFET 61 and the p-type MOSFET 62.

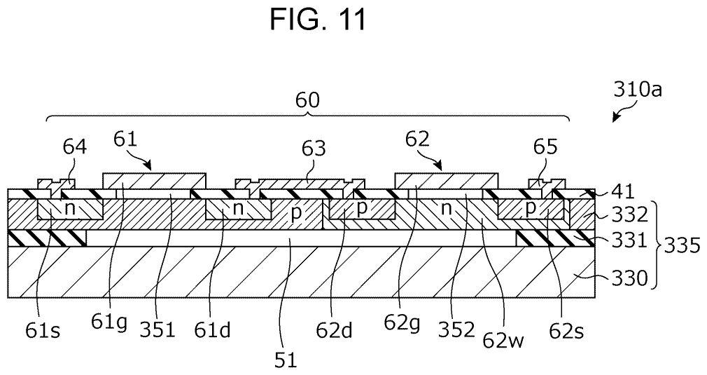

FIG. 11 is a sectional view of an infrared sensor element 310a according to a modification of Embodiment 4. As illustrated in FIG. 11, the infrared sensor element 310a has a configuration in which a portion of the gate oxide film of the n-type MOSFET 61 and the p-type MOSFET 62 has been removed from the infrared sensor element 310. In the example illustrated in FIG. 11, as the gate oxide film, a portion of the insulating film 41 below the gate 61g is removed to form a gap 351, and a portion of the insulating film 41 below the gate 62g is removed to form a gap 352. A portion of the insulating film 41 overlapping the gate 61g and a portion of the insulating film 41 overlapping the gate 62g are removed in a plan view. If the gate oxide film of the n-type MOSFET 61 and the p-type MOSFET 62 is entirely removed, the gate 61g and the gate 62g are warped upward due to the release of the internal stresses of the polycrystal silicon in the semiconductor layer 332, which causes a trouble in the transistor operation. Thus, by removing only the portions of the gate oxide film of the n-type MOSFET 61 and the p-type MOSFET 62, such upward warping can be suppressed. The gap 351 and the gap 352 are filled with a gas such as air or a gas such as decompressed air having a lower thermal conductivity than that of the insulating film 41.

In the infrared sensor element 10 according to any one of Embodiments 1 to 3 and an infrared sensor element according to Embodiment 5 (described later), the gate oxide film may be removed similarly to the infrared sensor element 310a.

### Embodiment 5

Next, an infrared sensor according to Embodiment 5 will be described. In Embodiment 5, a configuration in which a structure that supports a light receiver in midair has a phononic crystal structure will be described. In the following description, points different from Embodiments 1 to 4 will be mainly described, and description of common points will be omitted or simplified.

FIG. 12 is a sectional view illustrating an infrared sensor element 410 according to Embodiment 5. In FIG. 12, pores of a phononic crystal structure (described later) are not illustrated.

The infrared sensor according to the present embodiment has a configuration in which the infrared sensor element 10 of the infrared sensor according to any one of Embodiments 1 to 3 has been changed to the infrared sensor element 410.

As illustrated in FIG. 12, the infrared sensor element 410 according to the present embodiment is different from the infrared sensor element 310 according to Embodiment 4 in that the infrared sensor element 410 includes a thermoelectric converter 460 instead of the thermoelectric converter 60.

The thermoelectric converter 460 has a configuration in which the n-type MOSFET 61 and the p-type MOSFET 62 of the thermoelectric converter 60 have been changed to an n-type MOSFET 461 and a p-type MOSFET 462. The n-type MOSFET 461 includes a gate 461g formed by a phononic crystal structure being provided in at least a portion of the gate 61g of the n-type MOSFET 61. The p-type MOSFET 462 includes a gate 462g formed by a phononic crystal structure being provided in at least a portion of the gate 62g of the p-type MOSFET 62. In other words, the gate 461g of the n-type MOSFET 461 and the gate 462g of the p-type MOSFET 462 have the phononic crystal structure.

In order to increase the S/N ratio of the infrared detection signal by ensuring the temperature difference between the hot junction and the cold junction, it can be effective to form a phononic crystal structure having high thermal insulation in the semiconductor (the MOSFET in the present embodiment) located between the hot junction and the cold junction. While semiconductors doped with an impurity have conductivity, they generally have low thermal insulation because carriers also transport heat. However, by the phononic crystal structure being provided in at least the portions of the gate 461g and the gate 462g, the thermal insulation can be increased while the conductivity is maintained. Thus, by using the infrared sensor element 410, the thermal insulation of the n-type MOSFET 461 and the p-type MOSFET 462 is improved, and the temperature difference between the hot junction and the cold junction is ensured, so that the S/N ratio of the infrared detection signal can be increased. Alternatively, one of the gate 461g and the gate 462g does not have to have the phononic crystal structure.

An artificial phononic crystal structure processed in the semiconductor manufacturing process is a structure in which fine holes having a diameter of several tens of nanometers are dug and periodically arranged. The pitch of the pores is, for example, greater than or equal to 1 nm and less than or equal to 300 nm. The hole diameter of the pores is, for example, greater than or equal to 10 nm and less than or equal to 50 nm.

Since the wavelengths of phonons that carry heat mainly range from 1 nm to 300 nm, the phononic crystal structure tends to have high thermal insulation when the pitch is in such a range. The electron beam lithography is suitable for forming a phononic crystal structure having a pitch of greater than or equal to about 100 nm and less than or equal to about 300 nm. The block co-polymer (BCP) lithography is suitable for forming a phononic crystal structure having a pitch of greater than or equal to about 1 nm and less than or equal to about 100 nm. The material of the gate 461g and the gate 462g is, for example, polycrystal silicon, and fine through holes can be formed by applying the above-described lithography and dry etching. At this time, as long as the aspect ratio (hole depth/hole diameter) is less than or equal to 5, the etching gas easily advances into the holes, and the holes are easily processed. For example, the etching gas can etch holes with a diameter of 20 nm through a polycrystal silicon thin film with a thickness of 100 nm to form a phononic crystal structure with a hole diameter of 20 nm.

In order to further increase the thermal insulation of the n-type MOSFET 461 and the p-type MOSFET 462, the phononic crystal structure may be provided also in a portion of the n-type MOSFET 461 and the p-type MOSFET 462 other than the gate 461g and the gate 462g.

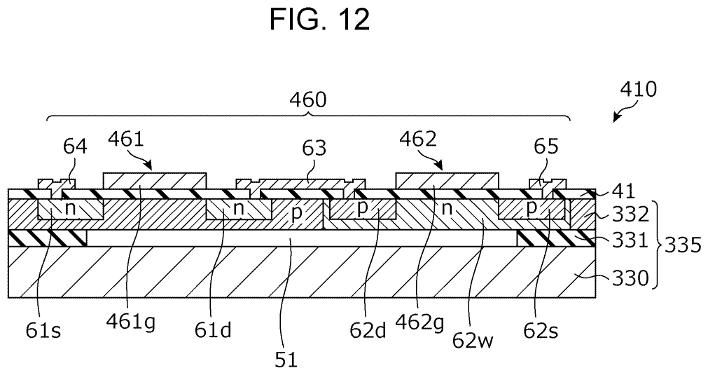

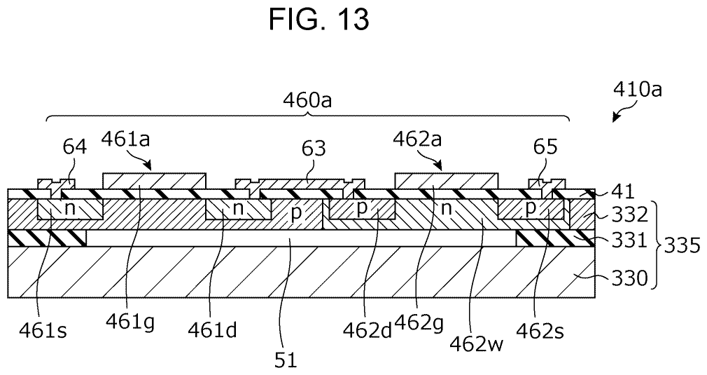

FIG. 13 is a sectional view of an infrared sensor element 410a according to a modification of Embodiment 5. In FIG. 13, pores of a phononic crystal structure (described later) are not illustrated.

The infrared sensor element 410a has a structure in which a phononic crystal structure is provided in the semiconductor layer 332 of the infrared sensor element 410. As illustrated in FIG. 13, the infrared sensor element 410a has a configuration in which the thermoelectric converter 460 of the infrared sensor element 410 has been changed to a thermoelectric converter 460a. The thermoelectric converter 460a is formed by a phononic crystal structure being provided in the n-type MOSFET 461 and the p-type MOSFET 462 of the thermoelectric converter 460 other than the gate 461g and the gate 462g.

The thermoelectric converter 460a includes an n-type MOSFET 461a and a p-type MOSFET 462a. A source 461s, a drain 461d, a gate 461g, and a channel region between the source 461s and the drain 461d of the n-type MOSFET 461a have a phononic crystal structure. A source 462s, a drain 462d, a gate 462g, and a channel region between the source 462s and the drain 462d of the p-type MOSFET 462a have a phononic crystal structure. The channel region of the p-type MOSFET 462a is a portion of a well 462w of the p-type MOSFET 462a. Accordingly, by using the infrared sensor element 410a, the thermal insulation of the n-type MOSFET 461a and the p-type MOSFET 462a is further increased, and the temperature difference between the hot junction and the cold junction is ensured, so that the S/N ratio of the infrared detection signal can be further improved. Alternatively, at least one of the source 461s, the drain 461d, the gate 461g, or the channel region of the n-type MOSFET 461a, or at least one of the source 462s, the drain 462d, the gate 462g, or the channel region of the p-type MOSFET 462a does not have to have the phononic crystal structure.

### Embodiment 6

Next, an infrared sensor according to Embodiment 6 will be described. In the following description, points different from Embodiments 1 to 5 will be mainly described, and description of common points will be omitted or simplified.

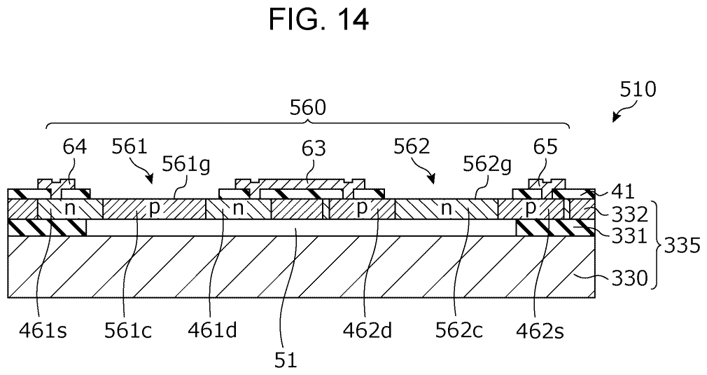

FIG. 14 is a sectional view illustrating an infrared sensor element 510 according to Embodiment 6. In FIG. 14, pores of a phononic crystal structure (described later) are not illustrated.

The infrared sensor according to the present embodiment has a configuration in which the infrared sensor element 10 of the infrared sensor according to any one of Embodiments 1 to 3 has been changed to the infrared sensor element 510.

As illustrated in FIG. 14, the infrared sensor element 510 according to the present embodiment is different from the infrared sensor element 410 according to Embodiment 5 in that the infrared sensor element 510 includes a thermoelectric converter 560 instead of the thermoelectric converter 460.

In the infrared sensor element 510, the semiconductor layer 332 is provided with a phononic crystal structure, similarly to the infrared sensor element 410a according to the modification of Embodiment 5.

The thermoelectric converter 560 has a configuration in which the n-type MOSFET 461 and the p-type MOSFET 462 of the thermoelectric converter 460 have been changed to an n-type MOSFET 561 and a p-type MOSFET 562.

The n-type MOSFET 561 includes the source 461s, the drain 461d, a gate 561g, and a channel region 561c between the source 461s and the drain 461d. The channel region 561c is formed by a phononic crystal structure being provided in a portion of the semiconductor layer 332 between the source 461s and the drain 461d. The source 461s, the drain 461d, the gate 561g, and the channel region 561c have a phononic crystal structure. In the example illustrated in FIG. 14, the channel region 561c is as thick as the semiconductor layer 332. In other words, the channel region 561c is formed over the entire region of the semiconductor layer 332 in the thickness direction. In FIG. 14, the gate 561g on the channel region 561c is very thin and hence is illustrated as having no thickness.

The p-type MOSFET 562 includes the source 462s, the drain 462d, a gate 562g, and a channel region 562c between the source 462s and the drain 462d. The channel region 562c is a portion of the well 462w of the above-described p-type MOSFET 462a between the source 462s and the drain 462d. The source 462s, the drain 462d, the gate 562g, and the channel region 562c have a phononic crystal structure. In the example illustrated in FIG. 14, the channel region 562c is as thick as the semiconductor layer 332. In other words, the channel region 562c is formed over the entire region of the semiconductor layer 332 in the thickness direction. In FIG. 14, the gate 562g on the channel region 562c is very thin and hence is illustrated as having no thickness.

In the present embodiment, the gate 561g is formed not only on the upper surface of the channel region 561c but also on the inner walls of pores ch1 of the phononic crystal structure in the channel region 561c. The gate 562g is formed not only on the upper surface of the channel region 562c but also on the inner walls of pores ch2 of the phononic crystal structure in the channel region 562c.

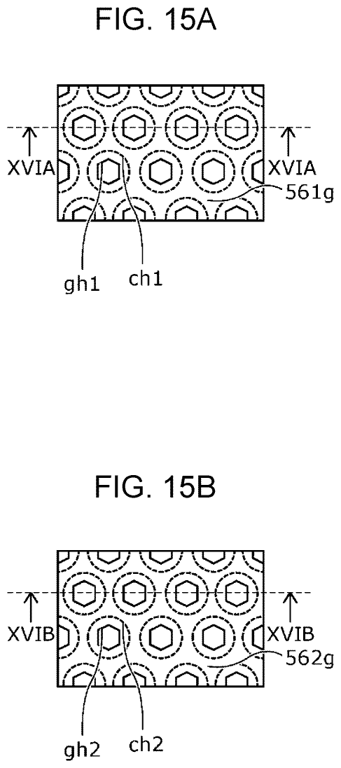

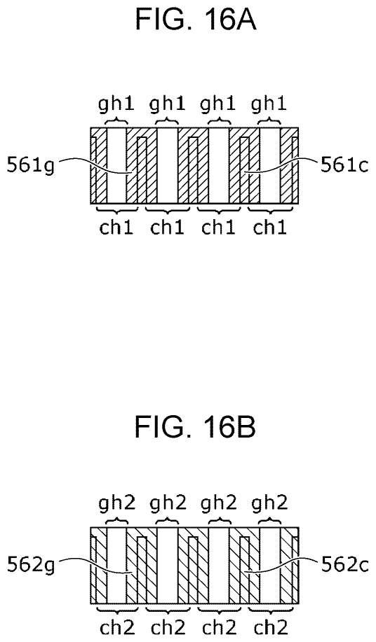

FIG. 15A is a plan view of a portion of the channel region 561c of the n-type MOSFET 561 as viewed from above. FIG. 15B is a plan view of a portion of the channel region 562c of the p-type MOSFET 562 as viewed from above. FIG. 16A is a sectional view of the portion of the channel region 561c of the n-type MOSFET 561. FIG. 16B is a sectional view of the portion of the channel region 562c of the p-type MOSFET 562. In FIG. 15A, the outline of the channel region 561c covered with the gate 561g is indicated by a broken line. In FIG. 15B, the outline of the channel region 562c covered with the gate 562g is indicated by a broken line. FIG. 16A illustrates a section taken along line XVIA-XVIA indicated in FIG. 15A. FIG. 16B illustrates a section taken along line XVIB-XVIB indicated in FIG. 15B.

As illustrated in FIG. 15A and FIG. 16A, in the n-type MOSFET 561, the gate 561g is formed not only on the upper surface of the channel region 561c but also on the inner walls of the periodic pores ch1 of the phononic crystal structure in the channel region 561c. Moreover, pores gh1 are periodically formed also in the gate 561g. Although not illustrated in FIG. 15A and FIG. 16A, a thin gate oxide film is formed between the gate 561g and the channel region 561c.

As illustrated in FIG. 15B and FIG. 16B, in the p-type MOSFET 562, the gate 562g is formed not only on the upper surface of the channel region 562c but also on the inner walls of the periodic pores ch2 of the phononic crystal structure in the channel region 562c. Moreover, pores gh2 are periodically formed also in the gate 562g. Although not illustrated in FIG. 15B and FIG. 16B, a thin gate oxide film is formed between the gate 562g and the channel region 562c.

With such a configuration, the gate 561g and the gate 562g can be formed with minimum volumes necessary for controlling the MOSFETs, and the gate 561g and the gate 562g also have the phononic crystal structure in which the periodic pores are formed, so that the thermal insulation of the gate 561g and the gate 562g is increased.

Moreover, since the channel region 561c and the channel region 562c are formed over the entire region of the semiconductor layer 332 in the thickness direction, the electric resistance of the channel region 561c and the channel region 562c is reduced when the signal voltage is applied to the gate 561g and the gate 562g, and the thermal noise generated from the resistance of the channels can be reduced when the voltage is applied to the gate 561g and the gate 562g to control the thermoelectric converter 560. Thus, by using the infrared sensor element 510, infrared information with a high S/N ratio can be acquired due to the effect of the temperature difference between the hot junction and the cold junction ensured by the thermal insulation of the gate 561g and the gate 562g and the effect of the reduction in thermal noise generated from the resistance of the channels.

Alternatively, in the infrared sensor element 510, at least one of the source 461s, the drain 461d, the gate 561g, the source 462s, the drain 462d, or the gate 562g does not have to have the phononic crystal structure. One of the channel region 561c and the channel region 562c does not have to have the phononic crystal structure.

### Other Embodiments

The infrared sensor according to the present disclosure has been described above based on the embodiments, but the present disclosure is not limited to these embodiments. Various modifications to the embodiments that can be conceived by those skilled in the art and other embodiments constructed by combination of some of the components of the embodiments are also included in the scope of the present disclosure, as long as they do not depart from the gist of the present disclosure.

For example, in the above-described embodiment, the first cold junction metal electrode 64 outputs the infrared detection signal to the amplifier 12, and the bias voltage V_{bias} is applied to the second cold junction metal electrode 65. However, this does not imply any limitation. The second cold junction metal electrode 65 may output the infrared detection signal to the amplifier 12, and the bias voltage V_{bias} may be applied to the first cold junction metal electrode 64.

In the above embodiments, any one of the thermoelectric converters 60, 460, 460a, and 560 includes one n-type MOSFET 61, 461, 461a, or 561 and one p-type MOSFET 62, 462, 462a, or 562, but this does not imply any limitation. The thermoelectric converter 60, 460, 460a, or 560 may include n-type MOSFETs 61, 461, 461a, or 561, and/or p-type MOSFETs 62, 462, 462a, or 562. In this case, the n-type MOSFETs 61, 461, 461a, or 561 are connected in series, and/or the p-type MOSFETs 62, 462, 462a, or 562 are connected in series. Accordingly, the total channel length in the thermoelectric converter 60, 460, 460a, or 560 can be increased, the distance between the hot junction and the cold junction can be increased, and the temperature difference between the hot junction and the cold junction can be easily ensured. Alternatively, at least one n-type MOSFET 61, 461, 461a, or 561 of the n-type MOSFETs 61, 461, 461a, or 561 may be changed to an n-type semiconductor. At least one p-type MOSFET 62, 462, 462a, or 562 of the p-type MOSFETs 62, 462, 462a, or 562 may be changed to a p-type semiconductor.

In the above-described embodiments, any one of the infrared sensor elements 10, 310, 310a, 410, 410a, and 510 includes one thermoelectric converter 60, 460, 460a, or 560, but this does not imply any limitation. The infrared sensor element 10, 310, 310a, 410, 410a, or 510 may include thermoelectric converters 60, 460, 460a, or 560. In this case, the thermoelectric converters 60, 460, 460a, or 560 are connected in series such that the n-type MOSFETs 61, 461, 461a, or 561 and the p-type MOSFETs 62, 462, 462a, or 562 are connected. Accordingly, the electromotive voltage of the infrared sensor element 10 can be increased by a factor of the number of the thermoelectric converters 60, 460, 460a, or 560, as compared with the case where the number of the thermoelectric converters 60, 460, 460a, or 560 is one. At least one thermoelectric converter 60, 460, 460a, or 560 of the thermoelectric converters 60, 460, 460a, or 560 may have a configuration including an n-type semiconductor and a p-type semiconductor instead of the n-type MOSFET 61, 461, 461a, or 561 and the p-type MOSFET 62, 462, 462a, or 562.

In the above-described embodiments, field effect transistors (FETs) other than MOSFETs, such as junction FETs, may be used instead of the n-type MOSFET 61, 461, 461a, or 561 and the p-type MOSFET 62, 462, 462a, or 562.

The infrared sensor according to the present disclosure can be used for various applications including applications of infrared sensors of related art such as infrared imaging devices. The infrared sensor according to the present disclosure can be achieved as a highly accurate infrared sensor without being cooled, and hence can be applied to a driving monitor capable of detecting a person at night, a simple thermography for efficiently performing the body temperature measurement of a group, and the like.

What is claimed is:

1. An infrared sensor comprising:
a light receiver; and
a thermoelectric converter that generates an infrared detection signal based on heat generated by the light receiver,
wherein the thermoelectric converter includes an n-type metal oxide semiconductor field effect transistor, which is referred to as MOSFET, a p-type MOSFET, a hot junction metal electrode, a first cold junction metal electrode, and a second cold junction metal electrode,
wherein the hot junction metal electrode is located on the light receiver or adjacent to the light receiver, and is in ohmic contact with a drain of the n-type MOSFET and a drain of the p-type MOSFET,
wherein the first cold junction metal electrode is in ohmic contact with a source of the n-type MOSFET, and
wherein the second cold junction metal electrode is in ohmic contact with a source of the p-type MOSFET.

2. The infrared sensor according to claim 1, further comprising:
an amplifier that amplifies the infrared detection signal generated by the thermoelectric converter,
wherein the amplifier is a voltage-input amplifier.

3. The infrared sensor according to claim 1, further comprising:
a substrate,
wherein the light receiver, the n-type MOSFET, and the p-type MOSFET are located above the substrate, and
wherein a gap is formed between the light receiver, the n-type MOSFET, and the p-type MOSFET, and the substrate.

4. The infrared sensor according to claim 3,
wherein at least one of a gate of the n-type MOSFET or a gate of the p-type MOSFET has a phononic crystal structure.

5. The infrared sensor according to claim 3,
wherein at least one of the source, the drain, or a channel region of each of the n-type MOSFET and the p-type MOSFET has a phononic crystal structure.

6. The infrared sensor according to claim 3,
wherein a channel region of at least one of the n-type MOSFET or the p-type MOSFET has a phononic crystal structure, and
wherein a gate of the at least one of the n-type MOSFET or the p-type MOSFET is formed on an inner wall of a pore of the phononic crystal structure.

7. The infrared sensor according to claim 1,
wherein a portion of a gate oxide film of at least one of the n-type MOSFET or the p-type MOSFET is removed.

8. The infrared sensor according to claim 1,
wherein a voltage having a periodically repetitive waveform is applied to a gate of the n-type MOSFET and a gate of the p-type MOSFET.
